(19) United States
(12) Patent Application Publication
(10) Pub. No.: US 2025/0365849 A1
(43) Pub. Date: Nov. 27, 2025

(54) MODULE UNIT AND ELECTRONIC DEVICE

(71) Applicants: FLOSFIA INC., Kyoto (JP); MITSUBISHI HEAVY INDUSTRIES, LTD., Tokyo (JP)

(72) Inventors: Daisuke ASA, Tokyo (JP); Masato ITO, Tokyo (JP); Shota OKUBO, Tokyo (JP); Masaya MITAKE, Tokyo (JP); Kengo TAKEUCHI, Kyoto (JP); Tatsuhiro NAKAZAWA, Kyoto (JP); Hiroshi KONDO, Kyoto (JP); Hirofumi KOMIYA, Kyoto (JP); Toshimi HITORA, Kyoto (JP)

(21) Appl. No.: 19/295,236

(22) Filed: Aug. 8, 2025

Related U.S. Application Data
(63) Continuation of application No. PCT/JP2024/004434, filed on Feb. 8, 2024.

(30) Foreign Application Priority Data
Feb. 9, 2023 (JP) 2023-018290

(51) Int. Cl. H05K 1/02; H05K 1/18

(52) U.S. Cl. CPC H05K 1/0203; H05K 1/182

(57) ABSTRACT

Provided is a module unit including: a wiring substrate; a power element-embedded substrate mounted on the wiring substrate; and a metal block disposed on a side of the wiring substrate on which the power element-embedded substrate is mounted, the metal block covering at least a portion of the power element-embedded substrate, the metal block having a recessed portion on a side thereof facing the power element-embedded substrate, at least a portion of the power element-embedded substrate is located in the recessed portion.

### CROSS REFERENCE TO RELATED APPLICATION

This application is a continuation-in-part application of International Patent Application No. PCT/JP2024/004434 (Filed on Feb. 8, 2024), which claims the benefit of priority from Japanese Patent Application No. 2023-018290 (filed on Feb. 9, 2023).

The entire contents of the above applications, which the present application is based on, are incorporated herein by reference.

### 1. FIELD OF THE INVENTION

The present disclosure relates to a module unit including a wiring substrate and a power element-embedded substrate.

### 2. DESCRIPTION OF THE RELATED ART

A power conversion device is known to include a first substrate, a second substrate longitudinally provided on the first substrate, an electronic component disposed on a surface on one side of the second substrate in a plate thickness direction, and a heat sink disposed along the second substrate on the one side.

It should be noted that the Background Art section is intended to provide embodiments of the present disclosure in a technical or operational context to aid those skilled in the art in understanding the scope and usefulness of the present disclosure. No description disclosed herein is considered prior art merely because it is included in the Background Art section unless it is expressly identified as such.

### SUMMARY OF THE INVENTION

The following presents a simplified summary of the disclosure, which is intended to provide a basic understanding to those skilled in the art. This summary is not intended to identify key elements of the embodiments disclosed herein or to delineate the scope thereof. This summary presents some of the concepts disclosed herein in a simplified form, which serves as a prelude to the more detailed description presented later.

According to an example of the present disclosure, there is provided a module unit including, a wiring substrate; a power element-embedded substrate mounted on the wiring substrate; and a metal block disposed on a side of the wiring substrate on which the power element-embedded substrate is mounted, the metal block covering at least a portion of the power element-embedded substrate, the metal block having a recessed portion on a side thereof facing the power element-embedded substrate, at least a portion of the power element-embedded substrate located in the recessed portion.

Thus, the module unit according to the present disclosure may improve noise suppression, heat dissipation, and/or fire resistance.

### BRIEF DESCRIPTION OF THE DRAWINGS

FIG. 1 is an exploded perspective diagram schematically illustrating a module unit according to a first embodiment.

FIG. 2 is a cross-sectional diagram schematically illustrating the module unit according to the first embodiment.

FIG. 3 is a perspective diagram schematically illustrating a metal block according to the first embodiment.

FIG. 4 is an equivalent circuit diagram of a semiconductor circuit including a power element according to the first embodiment.

FIG. 5 is a cross-sectional diagram schematically illustrating an example of a power element-embedded substrate according to the first embodiment.

FIG. 6A is a cross-sectional diagram schematically illustrating a method of fixing the module unit according to the first embodiment.

FIG. 6B is a cross-sectional diagram schematically illustrating a method of fixing the module unit according to the first embodiment.

FIG. 7 is an exploded perspective diagram schematically illustrating an electronic device in which the module unit according to the first embodiment is mounted on a mounting substrate.

FIG. 8 is a cross-sectional diagram schematically illustrating a module unit according to a modified example 1.

FIG. 9 is an exploded perspective diagram schematically illustrating the module unit according to the modified example 1.

FIG. 10 is a perspective diagram schematically illustrating a module unit according to a second embodiment.

FIG. 11 is a cross-sectional diagram schematically illustrating the module unit according to the second embodiment.

FIG. 12 is an exploded perspective diagram schematically illustrating a module unit according to a modified example 2.

FIG. 13 is a cross-sectional diagram schematically illustrating the module unit according to the modified example 2.

FIG. 14 is a cross-sectional diagram schematically illustrating a module unit according to a third embodiment.

FIG. 15 is a cross-sectional diagram schematically illustrating a module unit according to a fourth embodiment.

FIG. 16 is a cross-sectional diagram schematically illustrating a module unit according to a modified example 3.

FIG. 17 is a cross-sectional diagram schematically illustrating a module unit according to a modified example 4.

FIG. 18 is a block diagram illustrating an example of a control system applying a module unit according to an embodiment of the disclosure.

FIG. 19 is a circuit diagram illustrating an example of the control system applying a module unit according to an embodiment of the disclosure.

FIG. 20 is a block configuration diagram illustrating another example of the control system applying a module unit according to an embodiment of the disclosure.

FIG. 21 is a circuit diagram illustrating another example of the control system applying a module unit according to an embodiment of the disclosure.

FIG. 22 is a top view diagram schematically illustrating wiring of the module unit according to the first embodiment.

FIG. 23A is a cross-sectional diagram taken along the lines A-A of FIG. 22, which schematically illustrates the wiring of the module unit according to the first embodiment.

FIG. 23B is a cross-sectional diagram taken along the lines B-B of FIG. 22, which schematically illustrates the wiring of the module unit according to the first embodiment.

FIG. 23C is a cross-sectional diagram taken along the lines C-C of FIG. 22, which schematically illustrates the wiring of the module unit according to the first embodiment.

FIG. 23D is a cross-sectional diagram taken along the lines D-D of FIG. 22, which schematically illustrates the wiring of the module unit according to the first embodiment.

FIG. 24 is an exploded perspective diagram schematically illustrating the wiring of the module unit according to the first embodiment.

FIG. 25 is a cross-sectional diagram schematically illustrating an electronic device in which a module unit is mounted on a mounting substrate.

FIG. 26 is an exploded perspective diagram schematically illustrating the electronic device in which the module unit is mounted on the mounting substrate.

FIG. 27 is an exploded perspective diagram schematically illustrating a module unit according to a modified example 6.

### DETAILED DESCRIPTION

The aspects of the present disclosure and the various features and advantageous details thereof will be explained more fully with reference to the non-limiting aspects and examples described and/or illustrated in the accompanying drawings and detailed in the following description. It should be noted that the features illustrated in the drawings are not necessarily drawn to scale, as those skilled in the art would recognize, even if not explicitly stated herein. Also, it should be noted that one feature in one aspect may be employed alone or in combination with other features in other aspects. Descriptions of well-known components and processing techniques may be omitted so as to not unnecessarily obscure the aspects of the present disclosure. The examples used herein are intended merely to facilitate an understanding of ways in which the present disclosure may be practiced and to further enable those skilled in the art to practice the aspects of the present disclosure. Accordingly, the examples and aspects herein should not be construed as limiting the scope of the present disclosure, which is defined solely by the appended claims and the applicable law. Furthermore, similar reference numerals represent similar parts throughout the drawings disclosed herein.

The terms “first”, “second”, and the like may be used herein to describe various elements, but these elements should not be limited by these terms. These terms “first”, “second”, and the like are merely used to distinguish one element from another. For example, a first element may be termed a second element, and, similarly, a second element may be termed a first element, without departing from the scope of the present disclosure. As used herein, the term “and/or” includes any or all combinations of one or more of the associated listed items.

It should be understood that when an element such as a layer, region, or substrate is referred to as being “on” or extending “onto” another element, it may be directly on or extend directly onto the other element or an intervening element may also be present. In contrast, when an element is referred to as being “directly on” or extending “directly onto” another element, there is no intervening element present. Similarly, it should be understood that when an element such as a layer, region, or substrate is referred to as being “over” or extending “over” another element, it may be directly over or extend directly over the other element or an intervening element may also be present. In contrast, when an element is referred to as being “directly over” or extending “directly over” another element, there is no intervening element present. It should also be understood that when an element is referred to as being “connected” or “coupled” to another element, it may be directly connected or coupled to the other element or an intervening element may be present. In contrast, when an element is referred to as being “directly connected” or “directly coupled” to another element, there is no intervening element present. Furthermore, it should be understood that when an element is referred to as being “stacked” on another element, it may be directly stacked on the other element or an intervening element may be present. In contrast, when an element is referred to as being “directly stacked” on another element, there is no intervening element present.

The terminology used herein is for the purpose of describing particular aspects only and is not intended to be limiting of the present disclosure. It should be understood that the terms “comprise (or comprising)” or “include (or including)” specify the presence of stated elements, but do not preclude the presence of one or more other elements.

Unless otherwise defined, all terms (including technical and scientific terms) used herein have the same meaning as commonly understood by those skilled in the art to which the present disclosure belongs. Terms used herein should be interpreted as having a meaning that is consistent with their meaning in the context of this specification and the relevant art. It should be further understood that terms used herein should not be interpreted in an idealized or overly formal sense unless expressly defined so herein.

In the present disclosure, unless otherwise defined, a stacking direction of a wiring substrate (direction perpendicular to the wiring substrate surface) is described as the Y direction, and a stacking direction of a mounting substrate (direction perpendicular to the mounting substrate surface) is described as the Z direction. Moreover, in a module unit in which the power element-embedded substrate is mounted on a first surface side of the wiring substrate, “top (or upper or above)” is defined as an upper side which is the power element-embedded substrate side when viewed from the wiring substrate, and “bottom (or lower or below)” is defined as the lower side which is the wiring substrate side when viewed from the power element-embedded substrate. In the case of a structure in which the power element-embedded substrates are mounted on both sides of the wiring substrate, a separate definition is required. Moreover, in an electronic device, “top (or upper or above)” is defined as an upper side which is the module unit side as viewed from the mounting substrate, and “bottom (or lower or below)” is defined as the lower side which is the mounting substrate side as viewed from the module unit side. In this specification, a top view may be rephrased as a plan view.

A module unit disclosed herein is characterized as including: a wiring substrate; a power element-embedded substrate mounted on the wiring substrate; and a metal block disposed on a side of the wiring substrate on which the power element-embedded substrate is mounted, the metal block covering at least a portion of the power element-embedded substrate, the metal block having a recessed portion on a side thereof facing the power element-embedded substrate, at least a portion of the power element-embedded substrate located in the recessed portion.

### First Embodiment

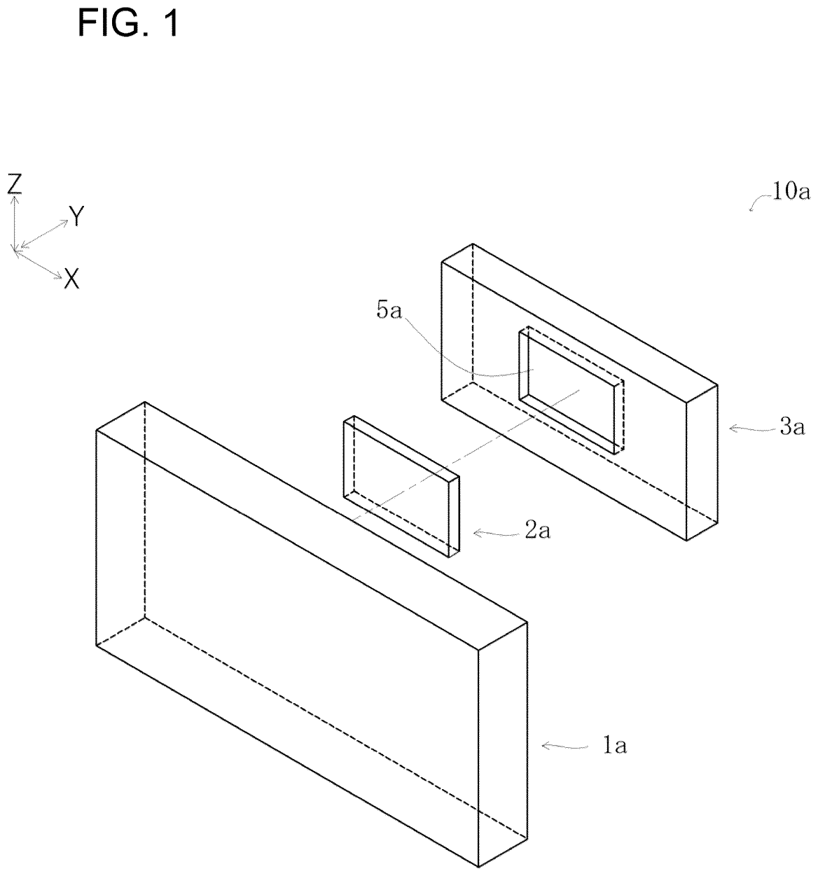

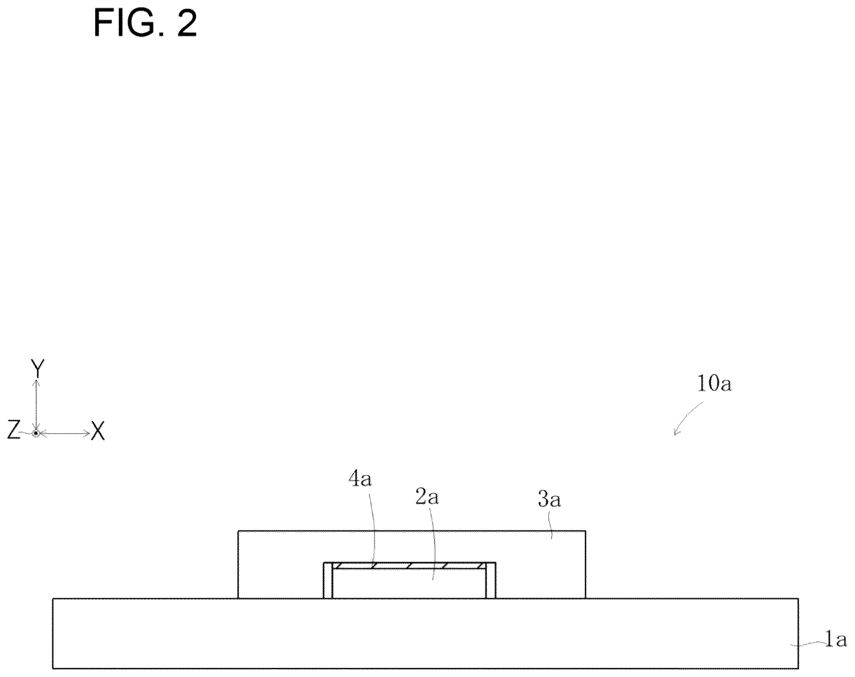

FIG. 1 is an exploded perspective diagram schematically illustrating a module unit 10a according to the first embodiment. FIG. 2 is a schematic cross-sectional diagram of the module unit 10a, illustrating a cross section of the module unit 10a illustrated in FIG. 1 taken in a stacking direction (Y direction). The module unit 10a illustrated in FIGS. 1 and 2 includes a wiring substrate 1a, a power element-embedded substrate 2a mounted on the wiring substrate 1a, and a metal block 3a. Although not illustrated in FIG. 1, an insulating member 4a is disposed between the metal block 3a and the power element-embedded substrate 2a, and the metal block 3a and the power element-embedded substrate 2a are thermally connected to each other through the insulating member 4a. It is to be noted that, in the module unit disclosed herein, the insulating member 4a is not essential, and the metal block 3a and at least a portion of the power element-embedded substrate 2a may be in direct contact with each other. In FIG. 1, electrical connections for the wiring substrate and each power element-embedded substrate are not illustrated, but these connections are realized using a well-known method.

As illustrated in FIGS. 1 and 2, in the present disclosure, the metal block 3a has a recessed portion 5a on a surface side facing the power element-embedded substrate 2a, and at least a portion of the power element-embedded substrate 2a is located inside the recessed portion 5a. In the present disclosure, it is sufficient that at least a portion of the power element-embedded substrate 2a is located inside the recessed portion 5a; it is not necessary for the entire power element-embedded substrate 2a to be located inside the recessed portion 5a as illustrated in FIG. 2. In FIG. 2, the power element-embedded substrate 2a is located inside a closed space formed by the metal block 3a and the wiring substrate 1a, but in the present disclosure, the space in which the power element-embedded substrate is located does not have to be completely closed. In the present disclosure, it is preferable that an upper surface of the power element-embedded substrate is thermally connected to the metal block, directly, or through another member. It is also preferable that at least a portion of a side surface (a surface perpendicular in the X direction in FIG. 2) of the power element-embedded substrate is covered with the metal block. In the present disclosure, it is preferable that at least a portion of the metal block 3a and the wiring substrate 1a are thermally connected to each other.

### (Wiring Substrate)

The wiring substrate 1a may be a dielectric substrate or may be a multilayered dielectric substrate. Moreover, the wiring substrate has a signal conductor pattern (not illustrated) wired on an upper surface and/or an inner layer thereof. Although not illustrated, the wiring substrate 1a may have an electrode pattern or an electrode pin for connecting to a connector on the mounting substrate side for establishing electrical connection with the mounting substrate. Furthermore, a circuit component (e.g., passive component, such as a capacitor) other than the power element may be mounted on the wiring substrate 1a.

### (Power Element-Embedded Substrate)

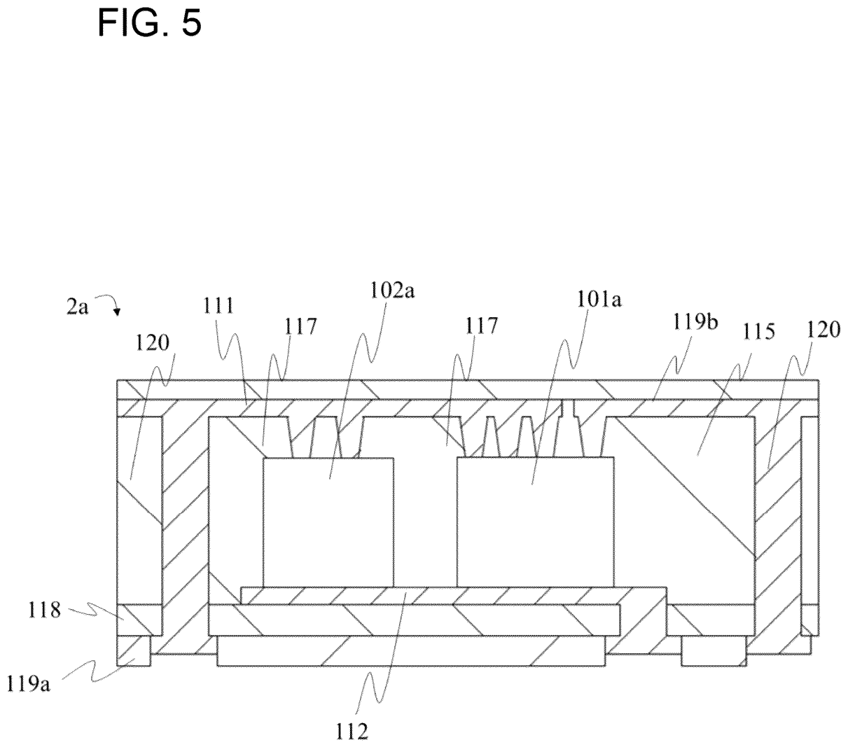

The power element-embedded substrate 2a is, for example, a multilayer wiring substrate in which a power element (diode, transistor, etc.) constituting a portion of the power conversion circuit is embedded. More specifically, for example, as illustrated in FIG. 5, the power element-embedded substrate 2a has a structure having an insulation layer 115 between a wiring layer (first wiring layer) 111 and a retention layer (second wiring layer) 112 so that a transistor 101a and a diode 102a as power elements are embedded in the insulation layer 115. In the power element-embedded substrate 2a illustrated in FIG. 5, the first wiring layer 111 constitutes an upper wiring layer, and the retention layer 112 constitutes a portion of the second wiring layer (lower wiring layer). The second wiring layer 112 is composed of a copper foil formed over both surfaces of a base material 118, and the copper foil on a first surface side of the base material 118 and a copper foil on a second surface side are electrically connected to each other through a through hole. Moreover, the diode 102a and the transistor 101a are placed respectively via adhesion layers (not illustrated) on the retention layer (copper foil on the first surface side) 112. The retention layer may constitute the second wiring layer, or may be composed of any other member (e.g., an insulating substrate, such as a metallic substrate or a ceramic substrate).

The diode 102a is, for example, a Schottky barrier diode (SBD), a fast recovery diode (FRD), or a PiN diode. Moreover, the transistor 101a is, for example, a metal oxide semiconductor field effect transistor (MOSFET) or an insulated gate bipolar transistor (IGBT). The semiconductor materials constituting the diode 102a and the transistor 101a as the power elements are not particularly limited. Examples of the semiconducting material include silicon, gallium nitride, silicon carbide, gallium oxide, and diamond. The power element-embedded substrate is manufactured using a known method of manufacturing a component-embedded substrate. A thickness of the power element-embedded substrate in the stacking direction (Y direction) is, for example, not more than 3 mm, or preferably not more than 1 mm. An area of the power element-embedded substrate as viewed from above is, for example, not more than 2000 mm², or preferably not more than 1000 mm².

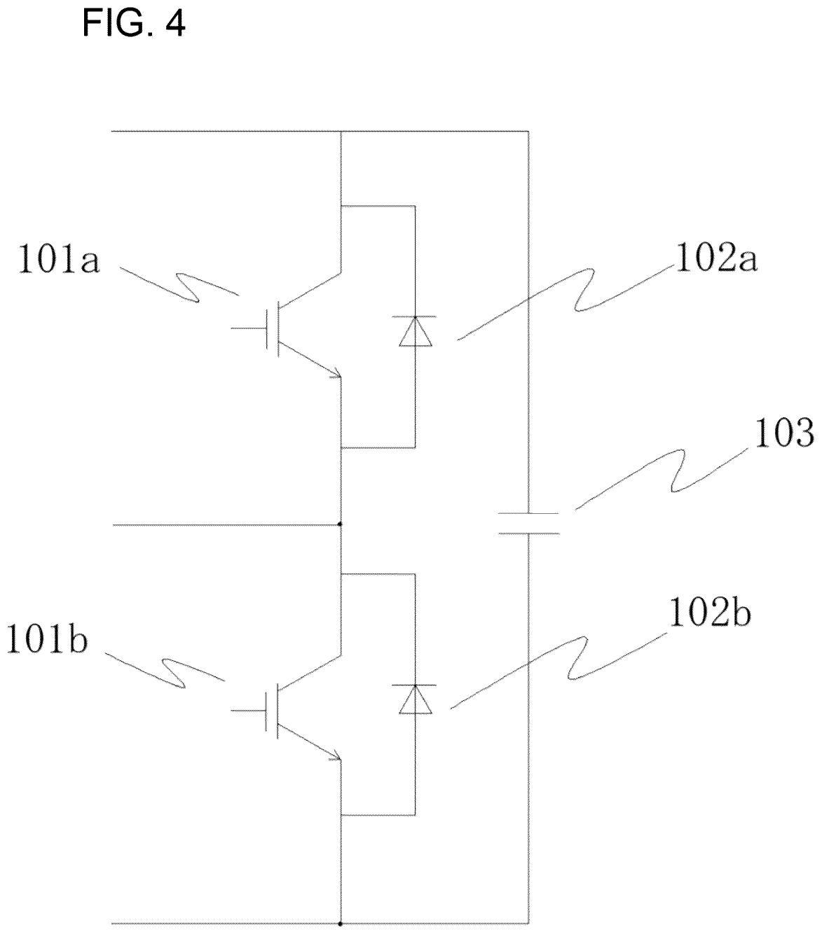

FIG. 4 is an equivalent circuit diagram for describing positioning in a circuit of a power element embedded in the power element-embedded substrate 2a. In a circuit configuration illustrated in FIG. 4, an anti-parallel circuit of a transistor 101a and a diode 102a and an anti-parallel circuit of a transistor 101b and a diode 102b are connected in series, and a capacitor 103 is further connected in parallel to the transistors 101a and 101b. The semiconductor circuit is applied to, for example, a power conversion circuit including an inverter circuit or a converter circuit. In the present embodiment, the power element-embedded substrate 2a is equipped with the transistor 101a and the diode 102a in the equivalent circuit illustrated in FIG. 4. In the present disclosure, the power element-embedded substrate 2a may be equipped with a plurality of transistors (e.g., transistors 101a and 101b) and/or a plurality of diodes (e.g., diodes 102a and 102b). When the power element-embedded substrate is equipped with a plurality of transistors, the plurality of transistors may be electrically connected in series or in parallel to each other. In the present disclosure, the module unit may include a plurality of power element-embedded substrates as will be described later. It should be noted that the circuit configuration described above is merely an example, and other circuit configurations may be used. In the present disclosure, the power conversion circuit may be configured by combining a plurality of the power element-embedded substrates together with other passive components.

### (Metal Block)

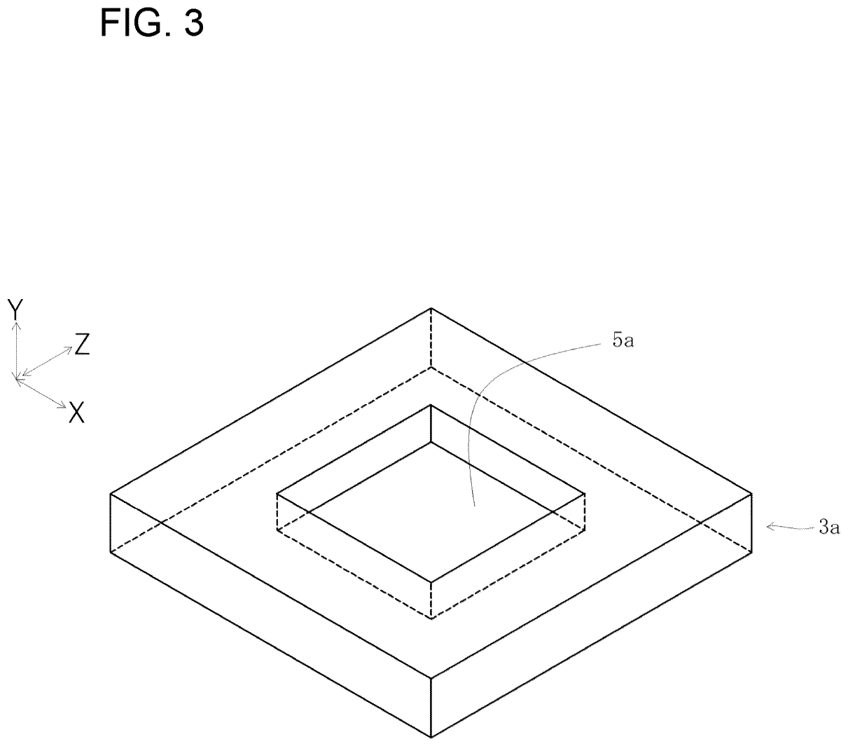

The metal block 3a is disposed in order to dissipate heat generated in the power element-embedded substrate. There are no particular limitations as long as the surface facing the power element-embedded substrate has a recessed portion. The metal block has, for example, a rectangular shape or circular shape in a plan view. Moreover, the metal block has a larger shape than the power element-embedded substrate in a plan view. FIG. 3 illustrates an example of the metal block. The recessed portion is formed using a well-known metal processing method (punching, laser machining, cut machining, metal plating, 3D printer, etc.). Moreover, the material constituting the metal block is not particularly limited as long as it does not hinder the object of the present disclosure. Examples of the material constituting the metal block include Cu, Au, Al, Ag, Fe, Ti, Ni, Pt, Pd, and alloys thereof (which may contain other metals or carbon, etc.). In the present disclosure, the material constituting the metal block preferably contains copper (Cu) or aluminum (Al), and more preferably contains aluminum (Al). In the present disclosure, as illustrated in FIG. 2, it is preferable that the periphery of the power element-embedded substrate is covered with the recessed portion of the metal block, and it is more preferable that the upper surface and the periphery thereof are covered. Moreover, a depth of the recessed portion is not particularly limited. The depth of the recessed portion is, for example, not more than 5 mm, preferably not more than 3 mm, and more preferably not more than 1 mm. In the present disclosure, when the wiring substrate further includes other passive components, the metal block may further include another recessed portion. In this case, at least a portion of the other passive component may be disposed in the other recessed portion. A depth of the other recessed portion is not particularly limited, and may be not less than 5 mm, or may be not more than 5 mm. Moreover, in the present disclosure, the metal block is preferably at the same potential as a ground potential of the power conversion circuit of which the power element constitutes a portion. Examples of a configuration in which the potential is the same as the ground potential include a configuration of being connected to a ground conductor (such as a housing) and a configuration of being in contact with a ground electrode of the wiring substrate.

In the present disclosure, for example, as illustrated in FIG. 2, the insulating member 4a may be disposed between the metal block 3a and the power element-embedded substrate 2a. The insulating member 4a preferably has high thermal conductivity, and more specifically, is made of a well-known Thermal Interface Material (TIM), such as a layer of a resin such as an epoxy resin containing a filler such as boron nitride (BN), aluminum nitride (AlN), or alumina (Al₂O₃). The insulating member and the power element-embedded substrate may be bonded to each other using a well-known electrical conductivity binder or the like.

### Example of Manufacturing Method

Hereinafter, a method of manufacturing the module unit having the above-described structure will be described.

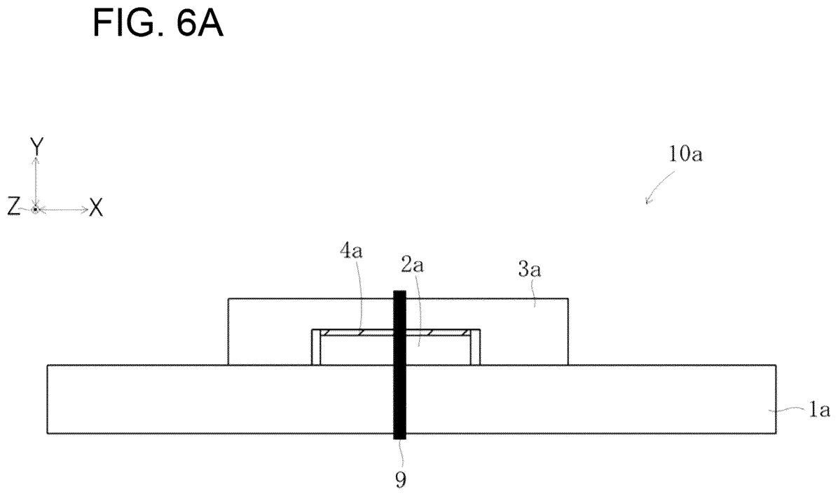

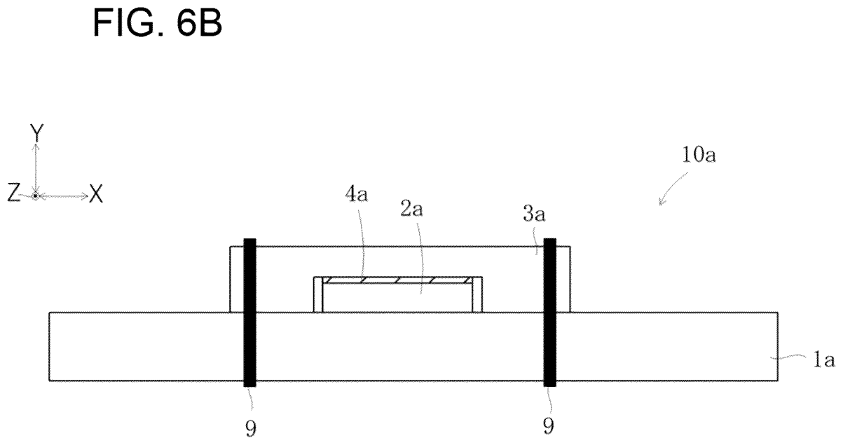

In an assembly process of the module unit, the power element-embedded substrate 2a is fixed into the recessed portion 5a of the metal block 3a. In this case, the insulating member 4a having excellent thermal conductivity may be interposed between the metal block 3a and the power element-embedded substrate 2a. Thereafter, the power element-embedded substrate 2a fixed to the metal block 3a is connected to the wiring substrate 1a. Subsequently, the metal block 3a and the wiring substrate are fixed to each other by, for example, screwing. FIGS. 6A and 6B illustrate examples of fixing by screwing. FIG. 6A shows an example of fastening the metal block 3a, the power element-embedded substrate 2a, and the wiring substrate 1a to each other with a screw passing through the power element-embedded substrate. By fastening them with the screw in this manner, adhesion between the power element-embedded substrate and the metal block is improved, thereby providing a configuration having more excellent heat dissipation. Moreover, FIG. 6B shows a configuration of fastening vicinities of end portions of the metal block 3a and the wiring substrate 1a with screws. According to such a configuration, since it is not necessary to form a through hole in the power element-embedded substrate, manufacturing becomes easier. Furthermore, the method of fixing each component of the module unit is not limited to the screw fastening, and any known method may be used. For example, a method of fixing using a busbar or a method of fixing using a clip may be used. Moreover, the electrical connection between the power element-embedded substrate and the wiring substrate may be performed by, for example, connecting each electrode pad exposed on a surface facing the wiring substrate of the power element-embedded substrate and a connection terminal on the side of the wiring substrate by a well-known method, such as soldering. The manufacturing method of the module unit described above is merely an example, and other methods may be used. For example, the assembly process of the module unit is not limited to the steps described above, and steps may be added or deleted, or the order of steps may be changed, without departing from the spirit and technical concept.

### Mounting Example on Mounting Substrate

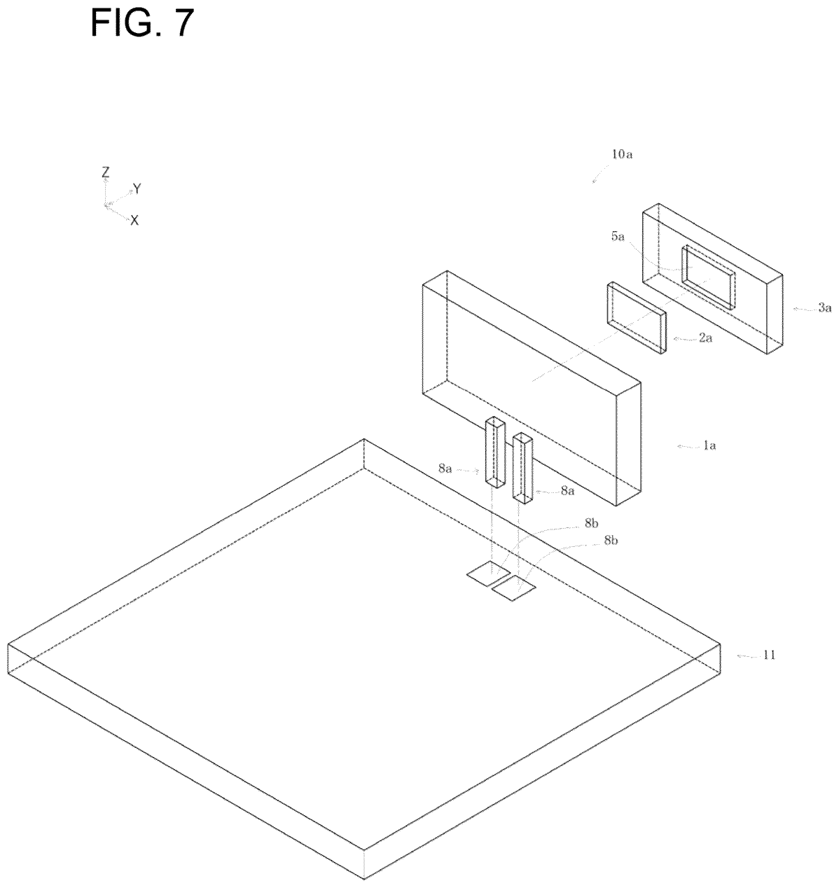

FIG. 7 illustrates an example of mounting the module unit 10a on the mounting substrate 11. A hole 8b for bonding with the electrode pin 8a of the module unit is formed in the mounting substrate 11 illustrated in FIG. 7. The electrode pin 8a is formed in a surface of the wiring substrate 1a on an opposite side to the power element-embedded substrate 2a of the module unit, and it is possible to longitudinally provide the wiring substrate 1a on the mounting substrate 11 by bonding the electrode pin 8a into the hole 8b, for example, by soldering. Although not illustrated, for example, a gate driver, an input terminal, an output terminal, a control IC, and other passive components may be mounted on the mounting substrate.

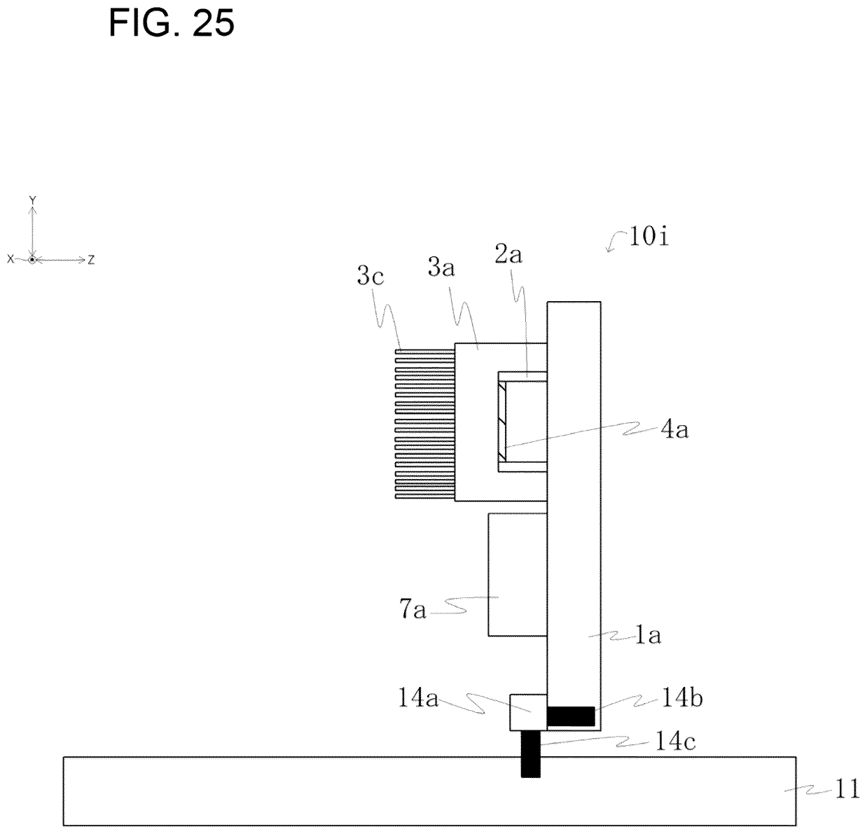

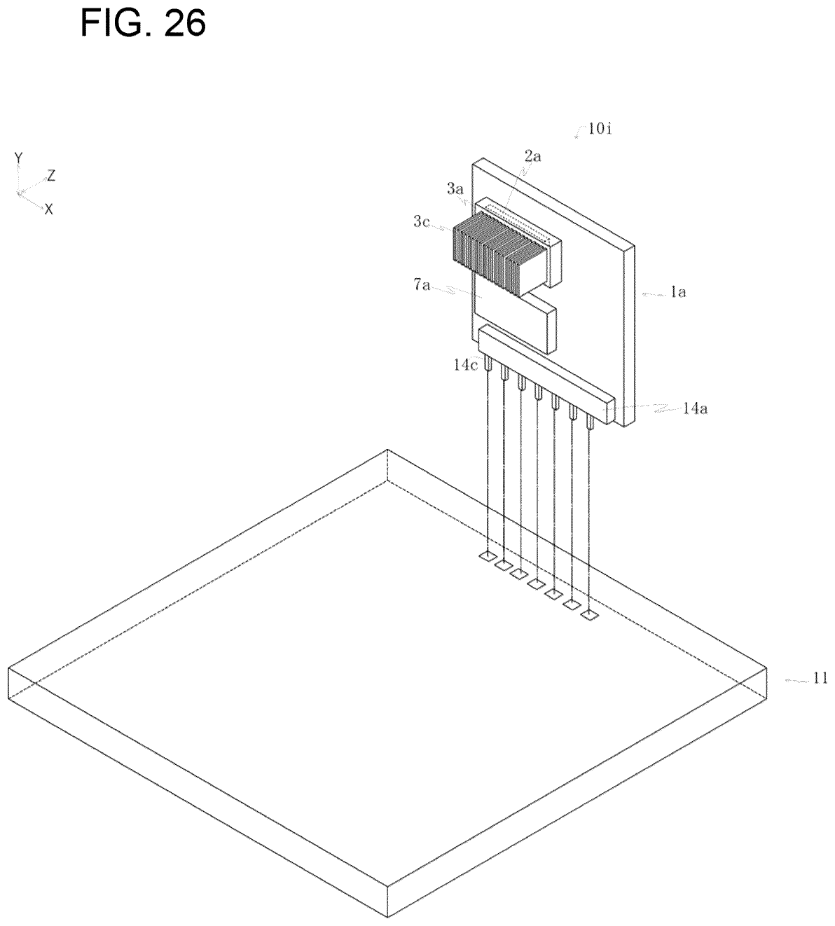

FIGS. 25 and 26 illustrate another example of an electronic device in which the module unit 10a is longitudinally provided on the mounting substrate 11. FIG. 25 illustrates a cross-sectional diagram schematically illustrating a state where a module unit 10i is longitudinally provided on a mounting substrate 11, and FIG. 26 illustrates an exploded perspective diagram thereof. As illustrated in FIGS. 25 and 26, the module unit 10i is connected to the mounting substrate 11 using a connection member including a resin portion 14a and a pin portion 14b. As illustrated in FIG. 25, the pin portion 14b extending in the Z direction so as to be connected to the wiring substrate 1a, and a pin portion 14a extending in the Y direction so as to be connected to the mounting substrate 11 are connected by being inserted into the resin portion 14a.

### Advantageous Effects of First Embodiment

As described above, the module unit 10a of the present embodiment has excellent heat dissipation, noise characteristics, and flame retardancy, since at least a portion of the power element-embedded substrate is located inside the recessed portion of the metal block having the recessed portion. From the viewpoint of noise characteristics and flame retardancy, it is preferable that the periphery of the power element-embedded substrate is covered with the recessed portion of the metal block as described above. Moreover, the module unit 10a of the present embodiment has excellent handleability since the wiring substrate, the power element-embedded substrate, and the metal block are integrated together. Furthermore, by combining a plurality of module units, it is possible to improve flexibility of implementation design of the entire power conversion circuit, for example, even without having to perform strict design of heat dissipation and noise characteristics.

### Modified Example 1

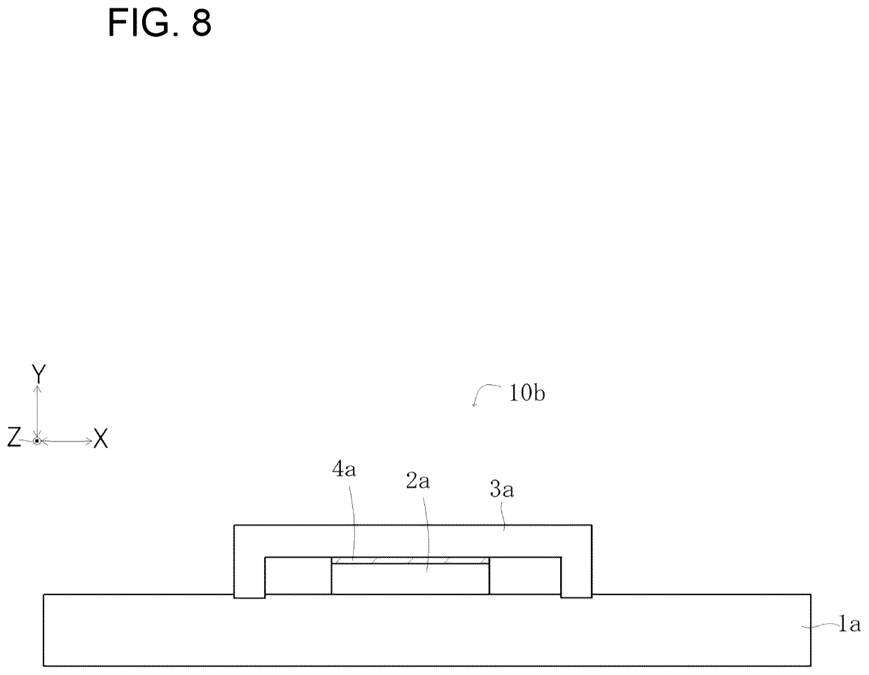

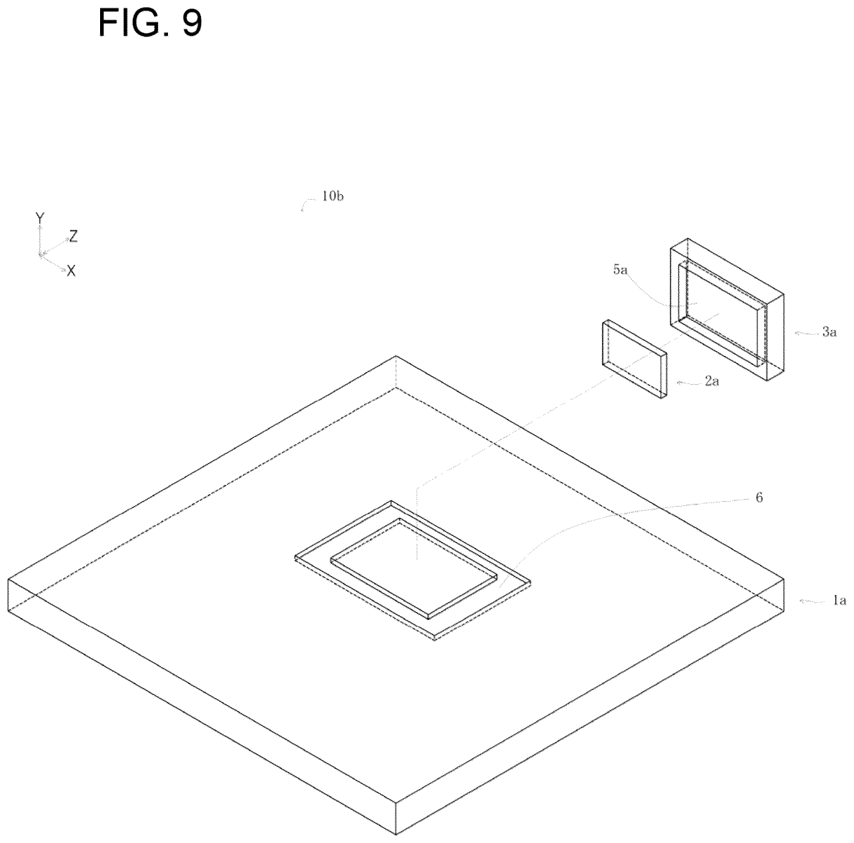

As a modified example 1, FIG. 8 illustrates an example of a module unit 10b in which a metal block 3a is fixed by being fitted to a recessed portion 6 of a wiring substrate 1a. FIG. 9 is a schematic perspective diagram of the module unit 10b illustrated in FIG. 8. This modified example illustrates that a ground electrode is exposed on a surface of the recessed portion 6 of the wiring substrate 1a, and a portion of the metal block 3a is fitted into the ground electrode portion on the recessed portion 6. According to such a configuration, it is possible to further improve the advantageous effect of noise suppression due to the metal block 3a. Moreover, it is possible to easily fix the metal block 3a, the power element-embedded substrate 2a, and the wiring substrate 1a to each other.

### Second Embodiment

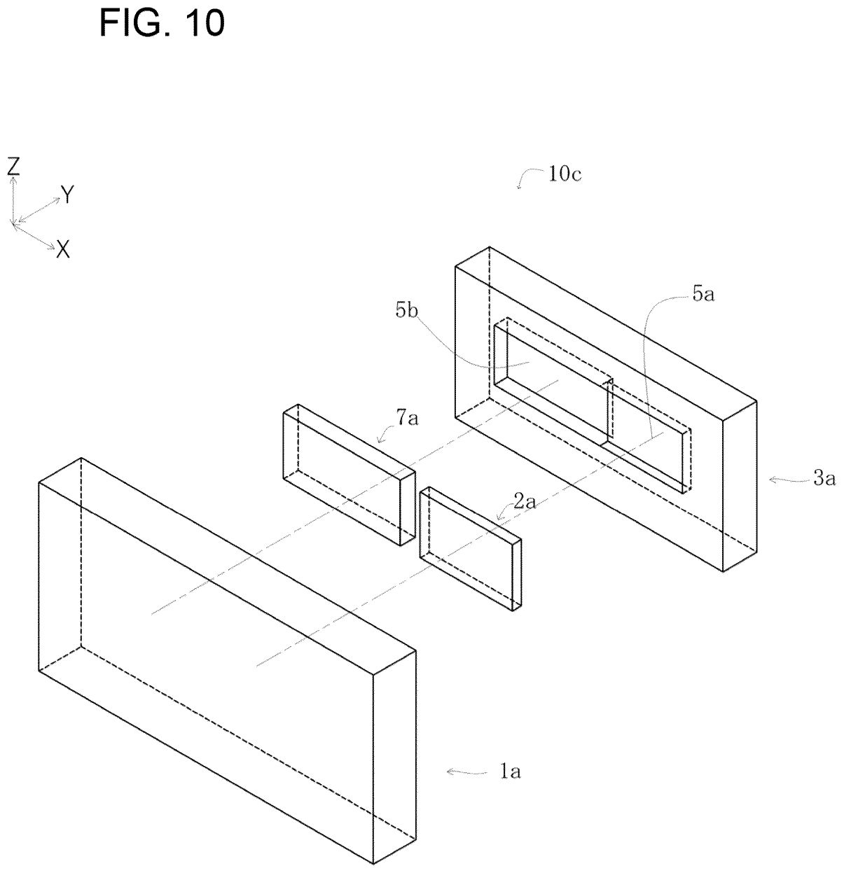

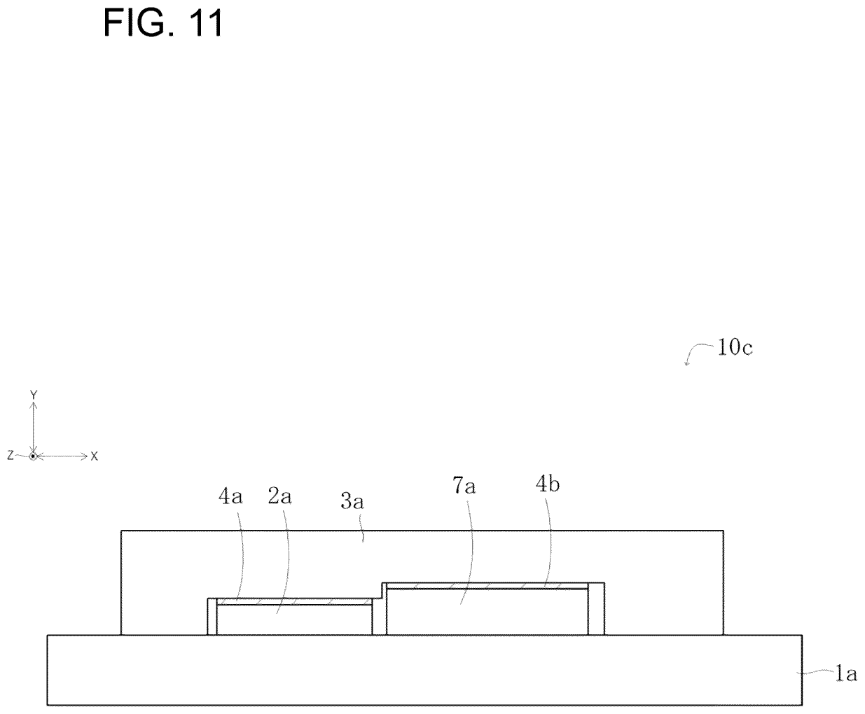

FIG. 10 is an exploded perspective diagram schematically illustrating a module unit 10c according to a second embodiment, and FIG. 11 illustrates a schematic cross-sectional diagram of the module unit 10c. In the module unit 10c in FIG. 10, a gate driver 7a configured to control a switching operation of the power element-embedded substrate 2a and power elements (transistors, etc.) in the power element-embedded substrate is mounted on the wiring substrate 1a. The gate driver 7a is disposed on the same side of the wiring substrate 1a as the power element-embedded substrate 2a. The gate driver 7a may be mounted on the wiring substrate 1a by using a well-known method. In the present embodiment, the metal block 3a has a recessed portion 5a and a recessed portion 5b on a surface facing the power element-embedded substrate 2a and the gate driver 7a, respectively. At this time, the recessed portion of the metal block 3a is formed so that at least a portion of the power element-embedded substrate 2a may be located inside the recessed portion 5a and at least a portion of the gate driver 7a may be located inside the recessed portion 5b. The recessed portion 5a and the recessed portion 5b of the metal block 3a may have depths different from each other respectively in accordance with heights of the power element-embedded substrate 2a and the gate driver 7a in the stacking direction (Y direction). An intermediate wall formed of the same material as the metal block may be disposed between the recessed portion 5a and the recessed portion 5b.

### Advantageous Effects of Second Embodiment

According to the module unit 10c illustrated in FIGS. 10 and 11, it is possible to realize a module unit capable of reducing an inductance between the power element-embedded substrate 2a and the gate driver 7a, and having excellent heat dissipation and noise suppression properties. Moreover, since at least a portion of the power element-embedded substrate 2a and the gate driver 7a are respectively located inside the recessed portions 5a and 5b of the metal block, it is possible to efficiently dissipate heat generated therein. Moreover, when an intermediate wall (formed of the same material as the metal block) is disposed between the recessed portion 5a and the recessed portion 5b, it is possible to further satisfactorily suppress noise between the power element-embedded substrate and the gate driver.

### Modified Example 2

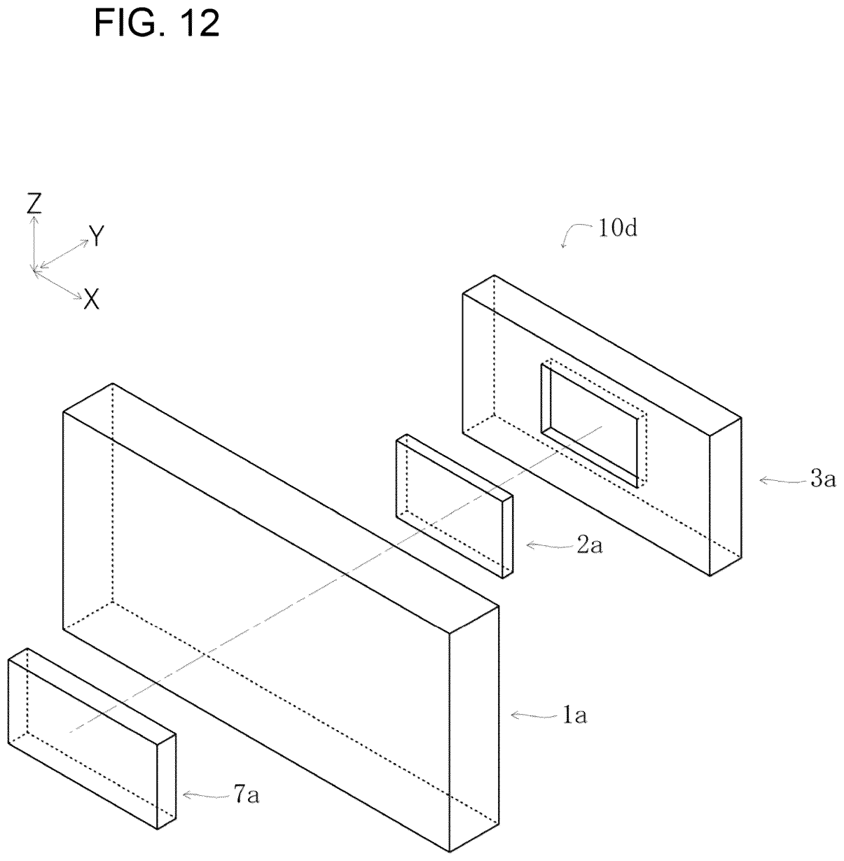

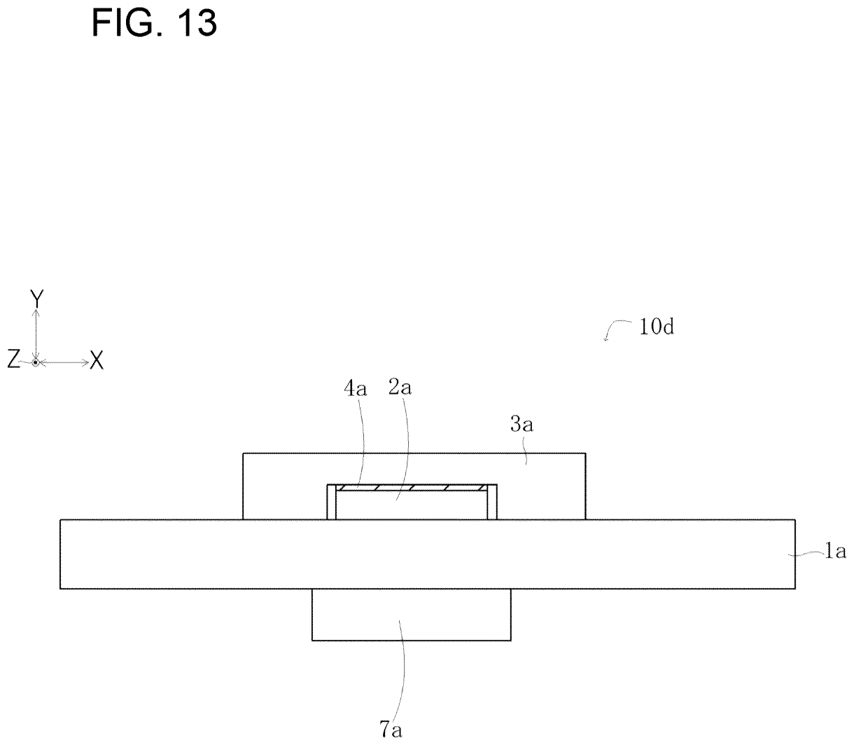

In a modified example 2, as illustrated in FIG. 12, a power element-embedded substrate 2a is mounted on a first surface side of a wiring substrate 1a, and a gate driver 7a is mounted on a second surface side of the wiring substrate 1a opposite to the first surface. FIG. 12 illustrates a schematic exploded perspective diagram of a module unit 10d, and FIG. 13 illustrates a cross-sectional diagram of the module unit 10d. According to such a configuration, in addition to the above-described advantageous effects of the second embodiment, it is possible to further reduce the area of the module unit and further reduce the inductance.

### Third Embodiment

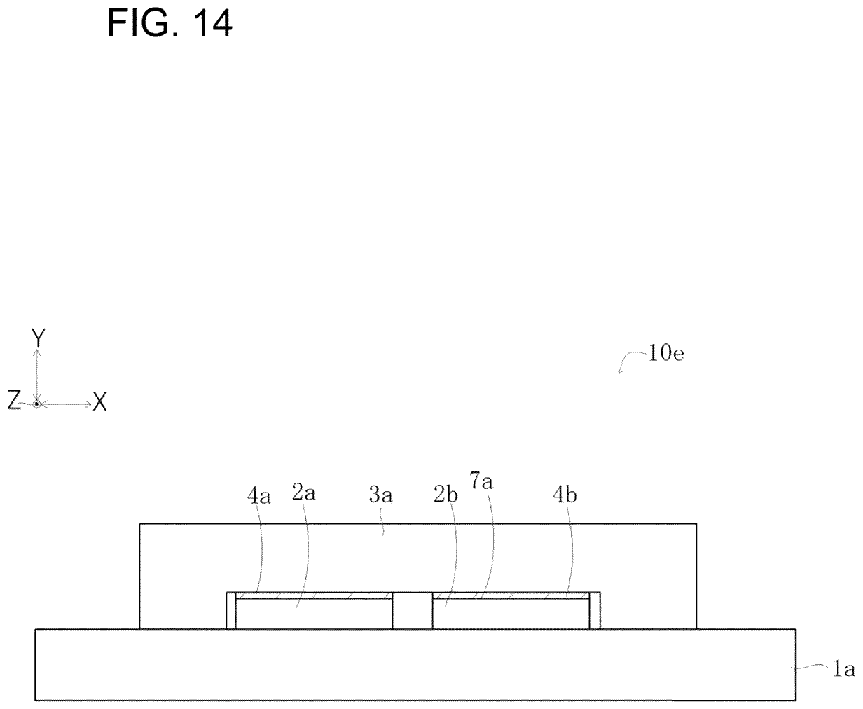

FIG. 14 is a schematic cross-sectional diagram illustrating a module unit 10e according to a third embodiment. In the module unit 10e illustrated in FIG. 14, a power element-embedded substrate 2a and a power element-embedded substrate 2b are mounted on a first surface side of a wiring substrate 1a, and a metal block 3a is disposed on the power element-embedded substrates 2a and 2b. The metal block 3a has a recessed portion on a surface side facing the power element-embedded substrates 2a and 2b, and at least a portion of the power element-embedded substrates 2a and 2b is located inside the recessed portion 5a. In the present embodiment, the power element-embedded substrate 2a is equipped with the transistor 101a and the diode 102a illustrated in FIG. 4, and the power element-embedded substrate 2b is equipped with the transistor 101b and the diode 102b illustrated in FIG. 4. In the present disclosure, for example, the transistors 101a and 101b and the diodes 102a and 102b illustrated in FIG. 4 may be respectively embedded in the power element-embedded substrate 2a and the power element-embedded substrate 2b as one unit.

### Advantageous Effects of Third Embodiment

According to the module unit 10e in FIG. 14, it is possible to easily realize a structure that satisfies a required current value, while also realizing a parallelizing function that allows some of the power element-embedded substrates to be partially disconnected from the circuit when they are damaged, so as to maintain the performance in the other substrates.

### Fourth Embodiment

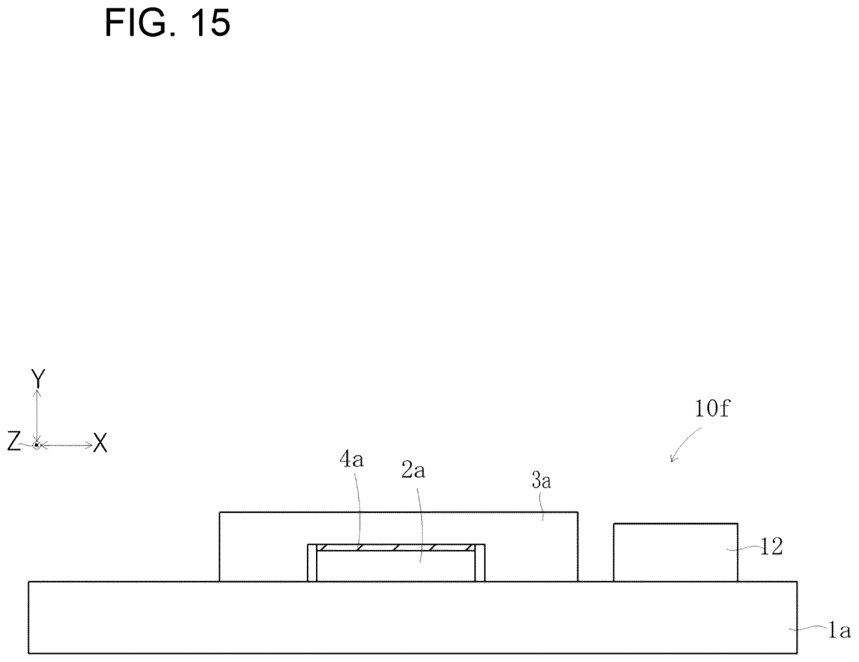

FIG. 15 is a schematic cross-sectional diagram illustrating a module unit 10f according to a fourth embodiment. The module unit 10f illustrated in FIG. 15 differs from the module unit 10a according to the first embodiment shown in FIGS. 1 and 2 in that a passive component 12 is mounted on the wiring substrate 1a. Examples of the passive component 12 include, for example, a capacitor, an inductor, and a resistor. The passive component 12 is mounted by a known method such as soldering or wire bonding. In the present embodiment, a wiring (not illustrated) connecting the passive component 12 and the power element-embedded substrate may be covered with the metal block 3a.

### Advantageous Effects of Fourth Embodiment

According to the module unit 10f illustrated in FIG. 15, it is possible to design the power element-embedded substrate and the passive component as a set and improve flexibility in designing the entire system. Moreover, the structure in which the wiring connecting the passive component 12 and the power element-embedded substrate (or the wiring substrate 1a) is covered with the metal block 3a is capable of further satisfactorily suppressing noise.

### Modified Example 3

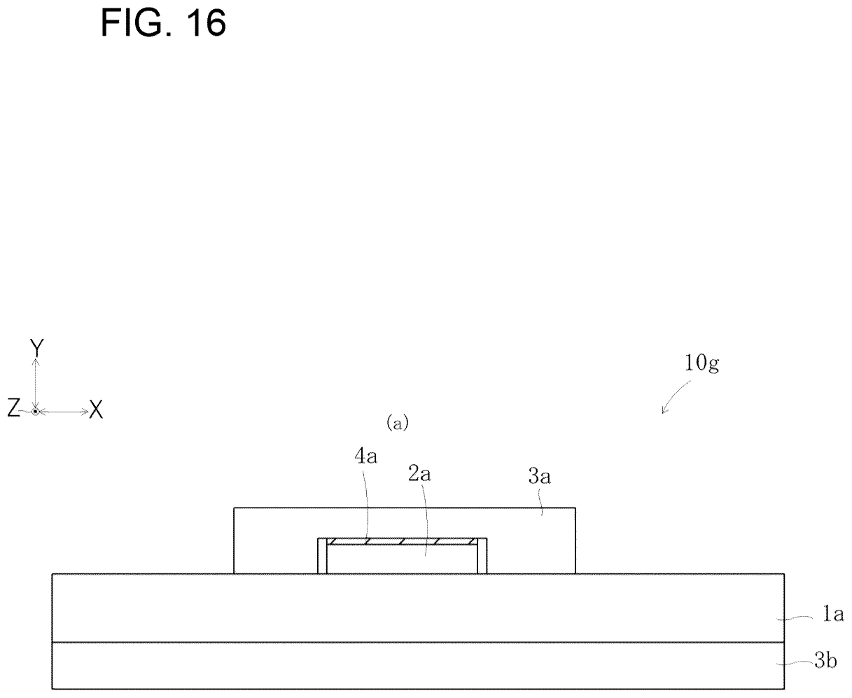

FIG. 16 is a schematic cross-sectional diagram illustrating a module unit 10g according to a modified example 3. The module unit 10g in FIG. 16 is characterized in that a heat dissipation member 3b is disposed on a surface of a wiring substrate opposite to a power element-embedded substrate 2a. According to the module unit 10g illustrated in FIG. 16, since the heat dissipation members (metal blocks) are arranged on both surfaces of the module unit 10g, it is possible to realize a configuration having excellent heat dissipation. Moreover, since the heat dissipation member is disposed also on a back surface side, it is possible to further downsize each heat dissipation member (metal block).

### Modified Example 4

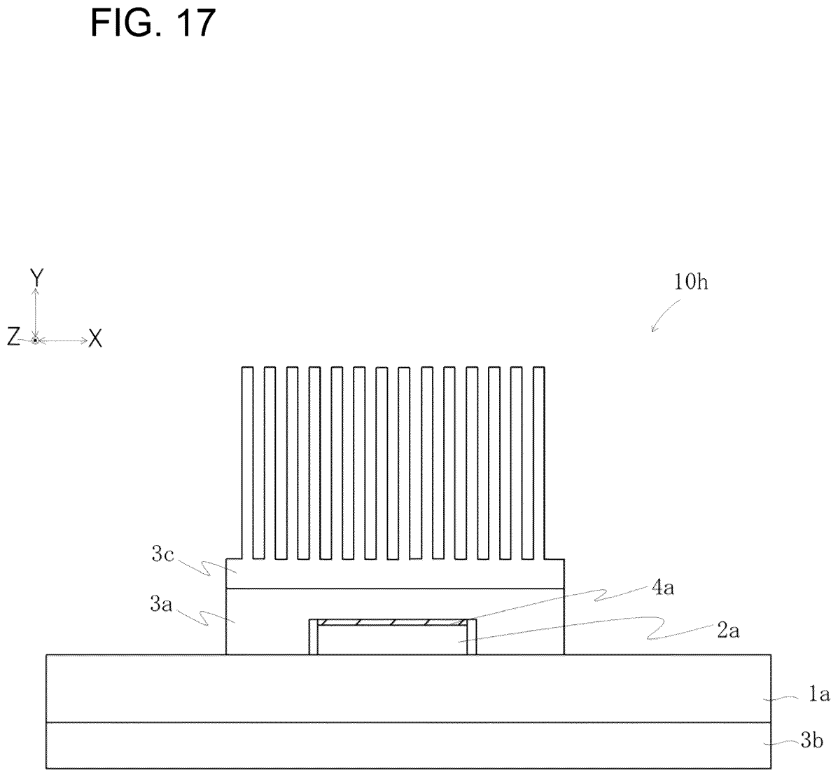

FIG. 17 is a schematic cross-sectional diagram illustrating a module unit 10h according to a modified example 4. In the module unit 10h according to the modified example 4 of the present disclosure, a cooler (heat radiation fin) 3c is further disposed on the metal block 3a for thermally dissipating heat generated in the power element-embedded substrate 2a. A constituent material of the cooler (heat radiation fin) 3c may be the same as that of the metal block, or a different material therefrom may be used. Moreover, this modified example illustrates an example in which the cooler is connected to the metal block 3a, but the configuration of the cooler is not particularly limited as long as it does not hinder the object of the present disclosure. For example, the metal block 3a may be configured to be connected to a housing in which the module unit 10a is mounted. Alternatively, the cooler (heat radiation fin) 3c may be connected to the heat dissipation member 3b side. In this modified example, since the heat dissipation members 3a and 3b are respectively disposed at both sides of the module unit 10, it is possible to further downsize the cooler (heat radiation fin) 3c.

### (Modified Example 5)

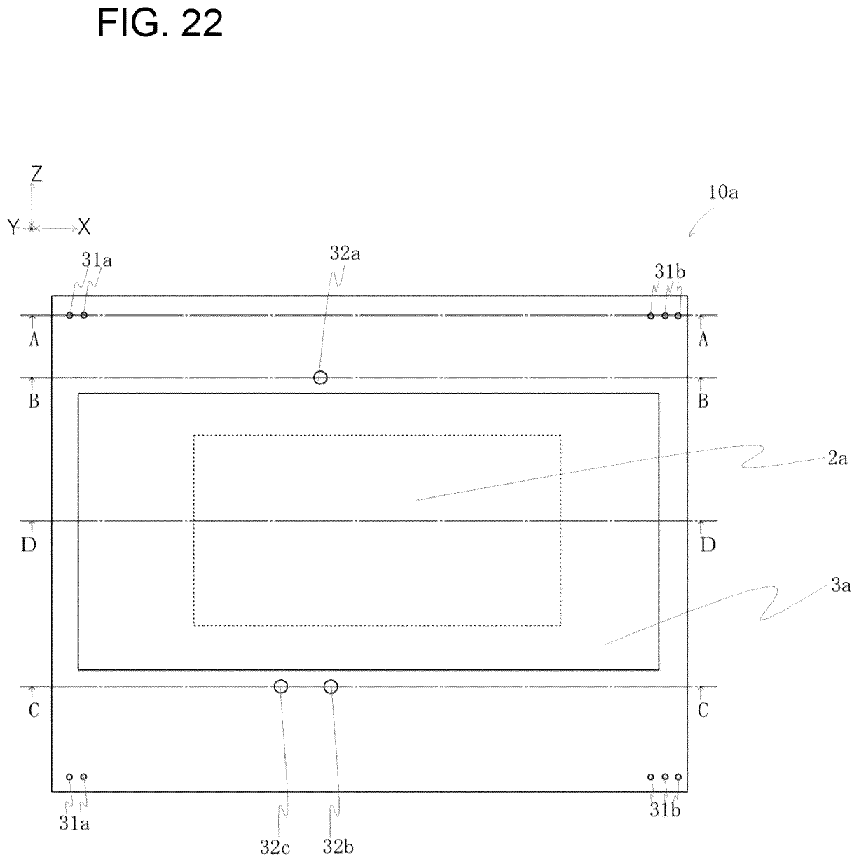

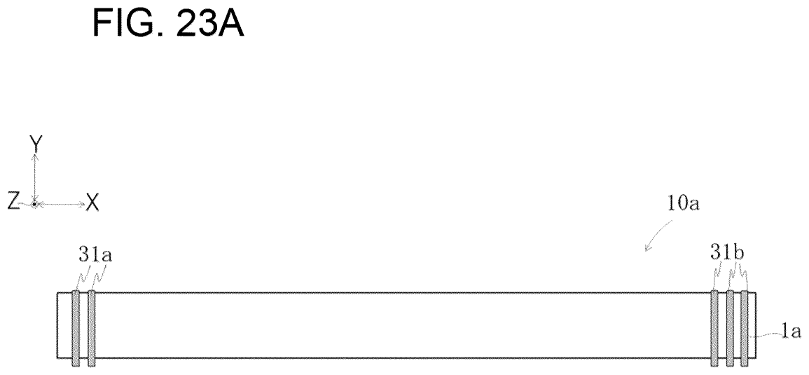

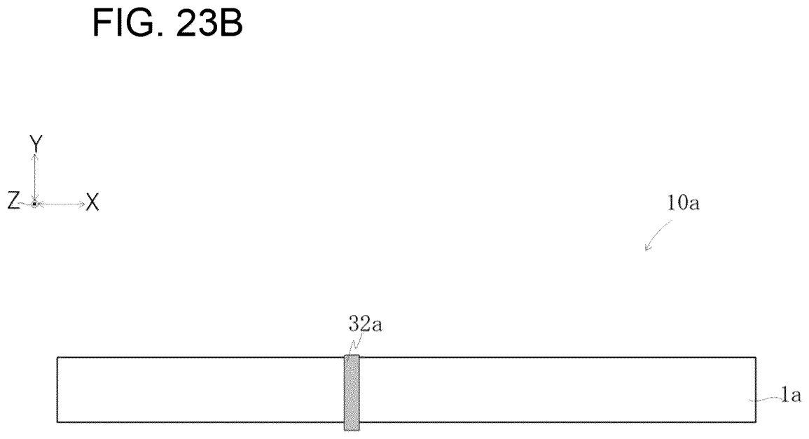

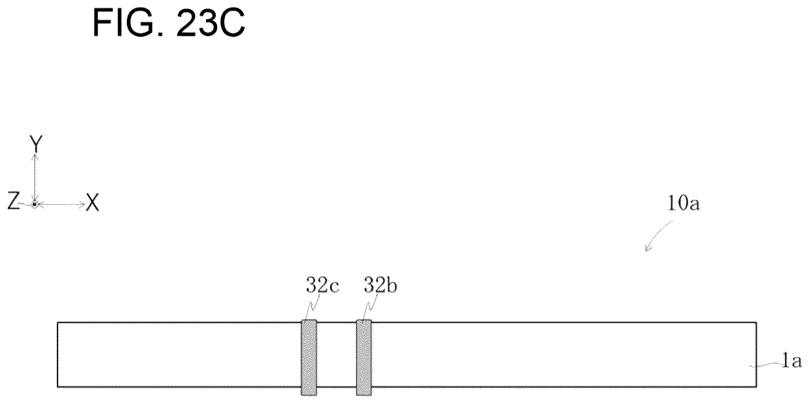

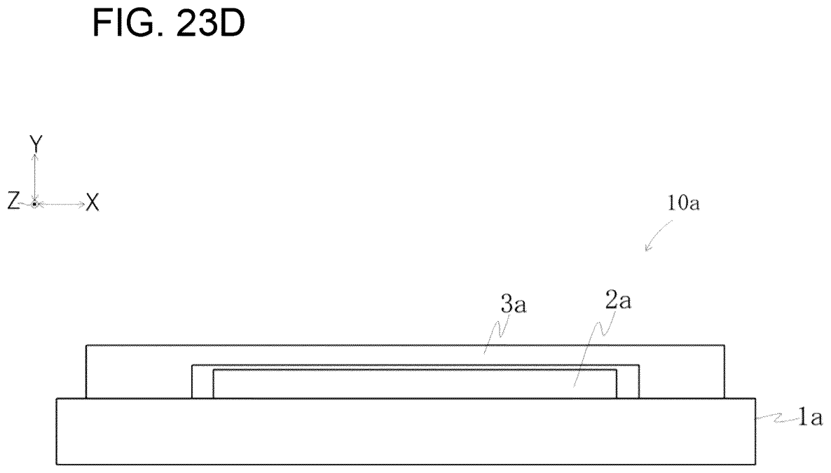

As a modified example 5, an example of a wiring pin in a module unit 10a of the present disclosure will now be described. FIGS. 22 and 23 are a top view diagram and a cross-sectional diagram schematically illustrating the module unit 10a according to the modified example 5. FIGS. 23A, 23B, 23C, and 23D illustrate respectively cross sections taken along the lines A-A, B-B, C-C, and D-D of FIG. 22. As illustrated in FIGS. 22 and 23, an input pin 32a, an output pin 32b, and a GND pin 32c for connecting a power element-embedded substrate of the module unit 10a to a power source, another component, a wiring substrate, and/or a mounting substrate, and power supply pins 31a and signal pins 31b for connecting the other component on the wiring substrate or the wiring substrate to other components, etc. are arranged to pass through the wiring substrate 1a. In the present disclosure, the input pin 32a, the output pin 32b and the GND pin 32c are electrically connected to corresponding electrode pads (signal pads, power supply pads, etc.) on the power element-embedded substrate 2a using wiring patterns or the like, which are not illustrated. In the present disclosure, the input pin 32a, the output pin 32b and the GND pin 32c are preferably located outside and near the outer periphery of the power element-embedded substrate in a plan view (top view).

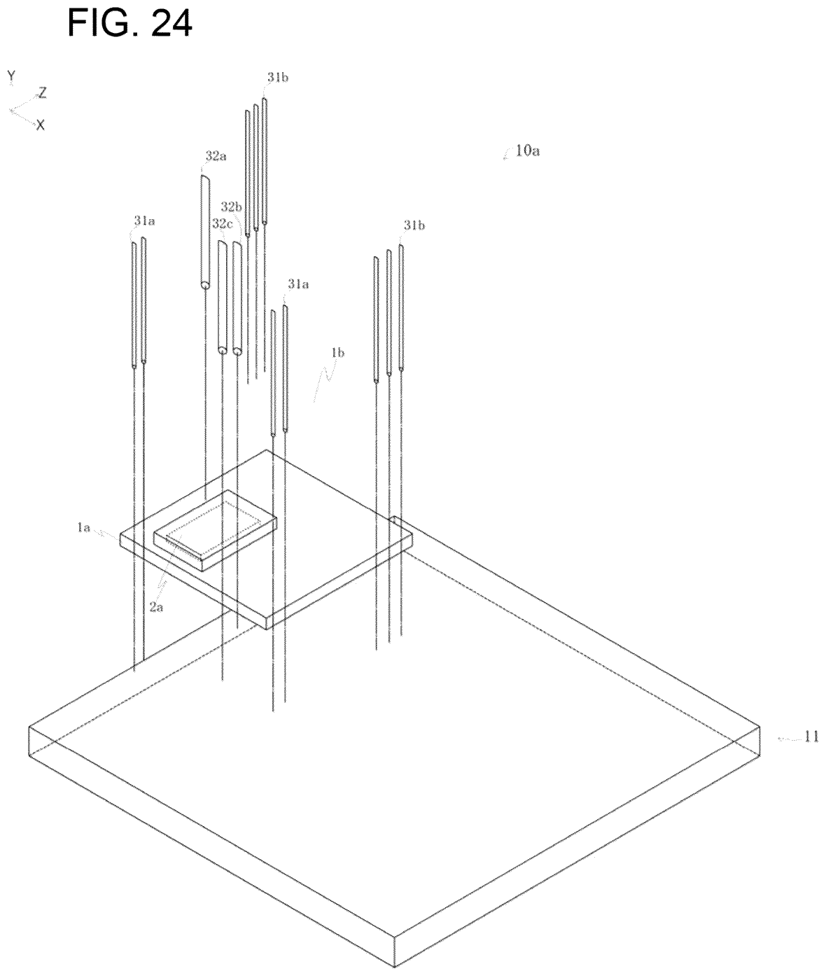

FIG. 24 is an exploded perspective diagram schematically illustrating an example of the module unit 10a in FIGS. 22 and 23 mounted on a mounting substrate 11. As illustrated in FIG. 24, the module unit 10a may be mounted so that each electrode pin (the input pin 32a, the output pin 32b, the GND pin 32c, the signal pins 31a, the power supply pins 31b) is inserted into the mounting substrate. In this case, a hole (not illustrated) corresponding to each pin may be formed on the mounting substrate 11.

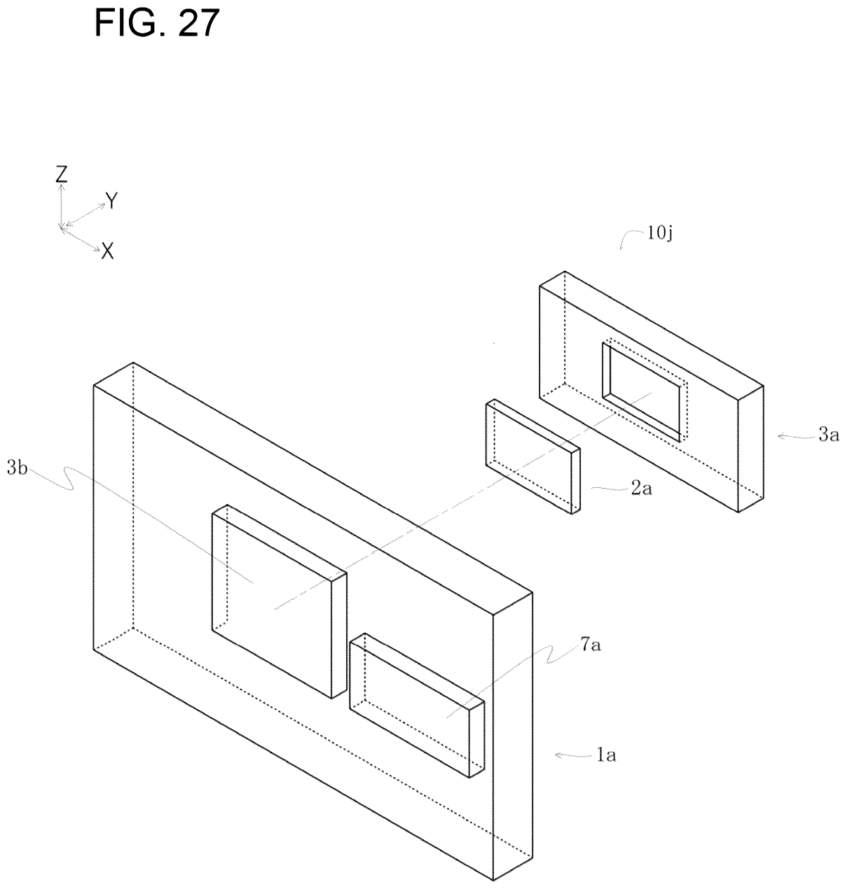

FIG. 27 is a schematic cross-sectional diagram illustrating a module unit 10j according to a modified example 6. In the module unit 10j in FIG. 27, a heat dissipation member 3b and a gate driver 7a for controlling a power element in a power element-embedded substrate 2a are arranged on a surface side of the wiring substrate opposite to the power element-embedded substrate 2a. According to the module unit 10j illustrated in FIG. 27, since the heat dissipation members (metal blocks) are arranged on both surfaces of the module unit 10j, it is possible to realize a configuration having excellent heat dissipation. Moreover, since the heat dissipation member is disposed also on a back surface side, it is possible to further downsize each heat dissipation member (metal block). Furthermore, according to the module unit 10j of FIG. 27, since the gate driver 7a is disposed on the back surface side, it is possible to further reduce inductance while minimizing the area of the substrate. Moreover, in the present disclosure, as in the module unit 10j in FIG. 27, the power element-embedded substrate 2a and the gate driver 7a may be disposed at positions not overlapping one another in a plan view (when viewed in the Y direction). By arranging in this manner, it is possible to further effectively reduce an influence of heat generated from the power element-embedded substrate 2a on the gate driver 7a. Alternatively, in the present disclosure, the power element-embedded substrate 2a and the gate driver 7a may partly overlap one another in a plan view (when viewed in the Y direction). When an overlapping rate in a plan view is small (e.g., in planar view not more than 50% of an area of the power element-embedded substrate, and preferably not more than 30%), it is possible to reduce the influence of heat.

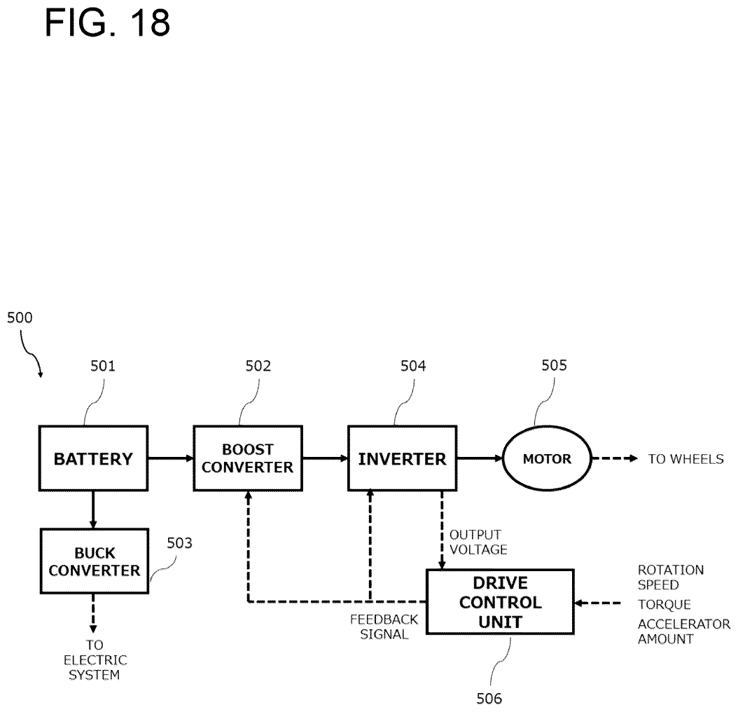

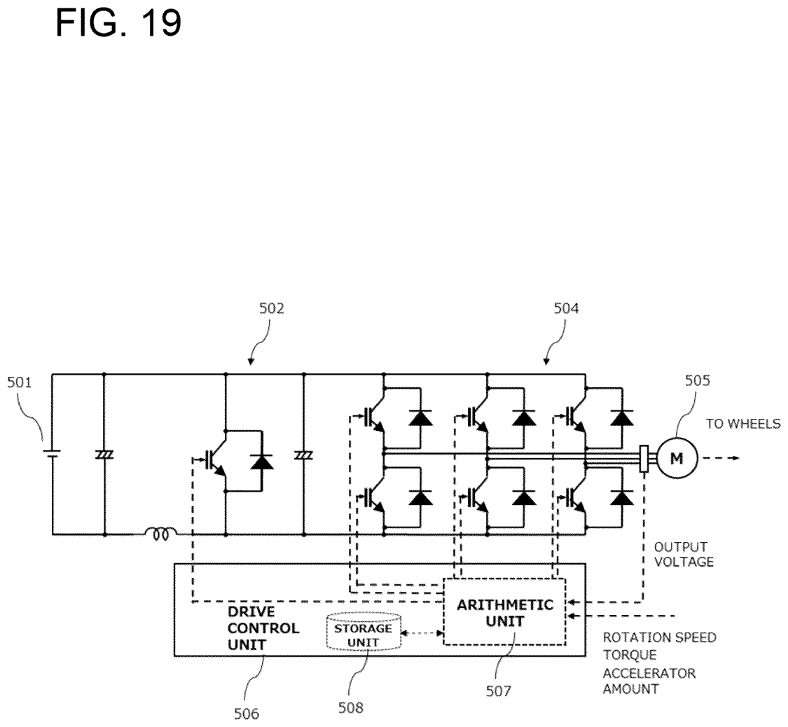

In order to exhibit the functions described above, the module unit and/or the electronic device of the disclosure described above may be applied to a power converter such as an inverter or a converter. FIG. 18 is a block diagram illustrating an exemplary control system applying a module unit according to an embodiment of the disclosure, and FIG. 19 is a circuit diagram of the control system particularly suitable for applying to a control system of an electric vehicle.

As shown in FIG. 18, the control system 500 includes a battery (power supply) 501, a boost converter 502, a buck converter 503, an inverter 504, a motor (driving object) 505, a drive control unit 506, which are mounted on an electric vehicle. The battery 501 consists of, for example, a storage battery such as a nickel hydrogen battery or a lithium-ion battery. The battery 501 may store electric power by charging at the power supply station or regenerating at the time of deceleration, and to output a direct current (DC) voltage required for the operation of the driving system and the electrical system of the electric vehicle. The boost converter 502 is, for example, a voltage converter in which a chopper circuit is mounted, and may step-up DC voltage of, for example, 200V supplied from the battery 501 to, for example, 650V by switching operations of the chopper circuit. The step-up voltage may be supplied to a traveling system such as a motor. The buck converter 503 is also a voltage converter in which a chopper circuit is mounted, and may step-down DC voltage of, for example, 200V supplied from the battery 501 to, for example, about 12V. The step-down voltage may be supplied to an electric system including a power window, a power steering, or an electric device mounted on a vehicle.

The inverter 504 converts the DC voltage supplied from the boost converter 502 into three-phase alternating current (AC) voltage by switching operations, and outputs to the motor 505. The motor 505 is a three-phase AC motor constituting the traveling system of an electric vehicle, and is driven by an AC voltage of the three-phase output from the inverter 504. The rotational driving force is transmitted to the wheels of the electric vehicle via a transmission mechanism (not shown).

On the other hand, actual values such as rotation speed and torque of the wheels, the amount of depression of the accelerator pedal (accelerator amount) are measured from an electric vehicle in cruising by using various sensors (not shown), The signals thus measured are input to the drive control unit 506. The output voltage value of the inverter 504 is also input to the drive control unit 506 at the same time. The drive control unit 506 has a function of a controller including an arithmetic unit such as a CPU (Central Processing Unit) and a data storage unit such as a memory, and generates a control signal using the inputted measurement signal and outputs the control signal as a feedback signal to the inverters 504, thereby controlling the switching operation by the switching elements. The AC voltage supplied to the motor 505 from the inverter 504 is thus corrected instantaneously, and the driving control of the electric vehicle may be executed accurately. Safety and comfortable operation of the electric vehicle is thereby realized. In addition, it is also possible to control the output voltage to the inverter 504 by providing a feedback signal from the drive control unit 506 to the boost converter 502.

FIG. 19 is a circuit configuration excluding the buck converter 503 in FIG. 18, in other words, a circuit configuration showing a configuration only for driving the motor 505. As shown in the FIG. 19, the module unit of the disclosure is provided for switching control by, for example, being applied to the boost controller 502 and the inverter 504 as a Schottky barrier diode. The boost converter 502 performs chopper control by incorporating the semiconductor device into the chopper circuit of the boost converter 502. Similarly, the inverter 504 performs switching control by incorporating the semiconductor device into the switching circuit including an IGBT of the inverter 504. The current may be stabilized by interposing an inductor (such as a coil) at the output of the battery 501. Also, the voltage may be stabilized by interposing a capacitor (such as an electrolytic capacitor) between each of the battery 501, the boost converter 502, and the inverter 504.

As indicated by a dotted line in FIG. 19, an arithmetic unit 507 including a CPU (Central Processing Unit) and a storage unit 508 including a nonvolatile memory are provided in the drive control unit 506. Signal input to the drive control unit 506 is given to the arithmetic unit 507, and a feedback signal for each semiconductor element is generated by performing the programmed operation as necessary. The storage unit 508 temporarily holds the calculation result by the calculation unit 507, stores physical constants and functions necessary for driving control in the form of a table, and outputs the physical constants, functions, and the like to the arithmetic unit 507 as appropriate. The arithmetic unit 507 and the storage unit 508 may be provided by a known configuration, and the processing capability and the like thereof may be arbitrarily selected.

As shown in FIGS. 18 and 19, a diode and a switching element such as a thyristor, a power transistor, an IGBT, a MOSFET and the like is employed for the switching operation of the boost converter 502, the buck converter 503 and the inverter 504 in the control system 500. The use of gallium oxide (Ga2O3) specifically corundum-type gallium oxide (α-Ga2O3) as its materials for these semiconductor devices greatly improves switching properties. Further, extremely outstanding switching performance may be expected and miniaturization and cost reduction of the control system 500 may be realized by applying a module unit or an electronic device of the disclosure. That is, each of the boost converter 502, the buck converter 503 and the inverter 504 may be expected to have the benefit of the disclosure, and the effect and the advantages may be expected in any one or combination of the boost converter 502, the buck converter 503 and the inverter 504, or in any one of the boost converter 502, the buck converter 503 and the inverter 504 together with the drive control unit 506.

The control system 500 described above is not only applicable to the control system of an electric vehicle of the module unit of the disclosure, but may be applied to a control system for any applications such as to step-up and step-down the power from a DC power source, or convert the power from a DC to an AC. It is also possible to use a power source such as a solar cell as a battery.

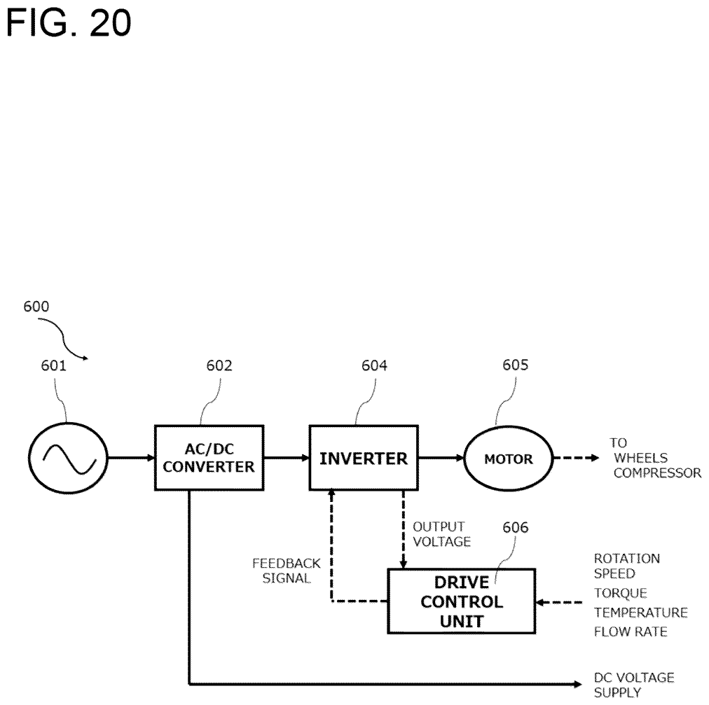

FIG. 20 is a block diagram illustrating another exemplary control system applying a module unit according to an embodiment of the disclosure, and FIG. 20 is a circuit diagram of the control system suitable for applying to infrastructure equipment and home appliances or the like operable by the power from the AC power source.

As shown in FIG. 20, the control system 600 is provided for inputting power supplied from an external, such as a three-phase AC power source (power supply) 601, and includes an AC/DC converter 602, an inverter 604, a motor (driving object) 605 and a drive control unit 606 that may be applied to various devices described later. The three-phase AC power supply 601 is, for example, a power plant (such as a thermal, hydraulic, geothermal, or nuclear plant) of an electric power company, whose output is supplied as an AC voltage while being downgraded through substations. Further, the three-phase AC power supply 601 is installed in a building or a neighboring facility in the form of a private power generator or the like for supplying the generated power via a power cable. The AC/DC converter 602 is a voltage converter for converting AC voltage to DC voltage. The AC/DC converter 602 converts AC voltage of 100V or 200V supplied from the three-phase AC power supply 601 to a predetermined DC voltage. Specifically, AC voltage is converted by a transformer to a desired, commonly used voltage such as 3. 3V, 5V, or 12V. When the driving object is a motor, conversion to 12V is performed. It is possible to adopt a single-phase AC power supply in place of the three-phase AC power supply. In this case, same system configuration may be realized if an AC/DC converter of the single-phase input is employed.

The inverter 604 converts the DC voltage supplied from the AC/DC converter 602 into three-phase AC voltage by switching operations and outputs to the motor 605. Configuration of the motor 605 is variable depending on the control object. It may be a wheel if the control object is a train, may be a pump and various power source if the control objects a factory equipment, may be a three-phase AC motor for driving a compressor or the like if the control object is a home appliance. The motor 605 is driven to rotate by the three-phase AC voltage output from the inverter 604, and transmits the rotational driving force to the driving object (not shown).

There are many kinds of driving objects such as personal computer, LED lighting equipment, video equipment, audio equipment and the like capable of directly supplying a DC voltage output from the AC/DC converter 602. In that case the inverter 604 becomes unnecessary in the control system 600, and a DC voltage from the AC/DC converter 602 is supplied to the driving object directly as shown in FIG. 20. Here, DC voltage of 3. 3V is supplied to personal computers and DC voltage of 5V is supplied to the LED lighting device for example.

On the other hand, rotation speed and torque of the driving object, measured values such as the temperature and flow rate of the peripheral environment of the driving object, for example, is measured using various sensors (not shown), these measured signals are input to the drive control unit 606. At the same time, the output voltage value of the inverter 604 is also input to the drive control unit 606. Based on these measured signals, the drive control unit 606 provides a feedback signal to the inverter 604 thereby controls switching operations by the switching element of the inverter 604. The AC voltage supplied to the motor 605 from the inverter 604 is thus corrected instantaneously, and the operation control of the driving object may be executed accurately. Stable operation of the driving object is thereby realized. In addition, when the driving object may be driven by a DC voltage, as described above, feedback control of the AC/DC converter 602 is possible in place of feedback control of the inverter 604.

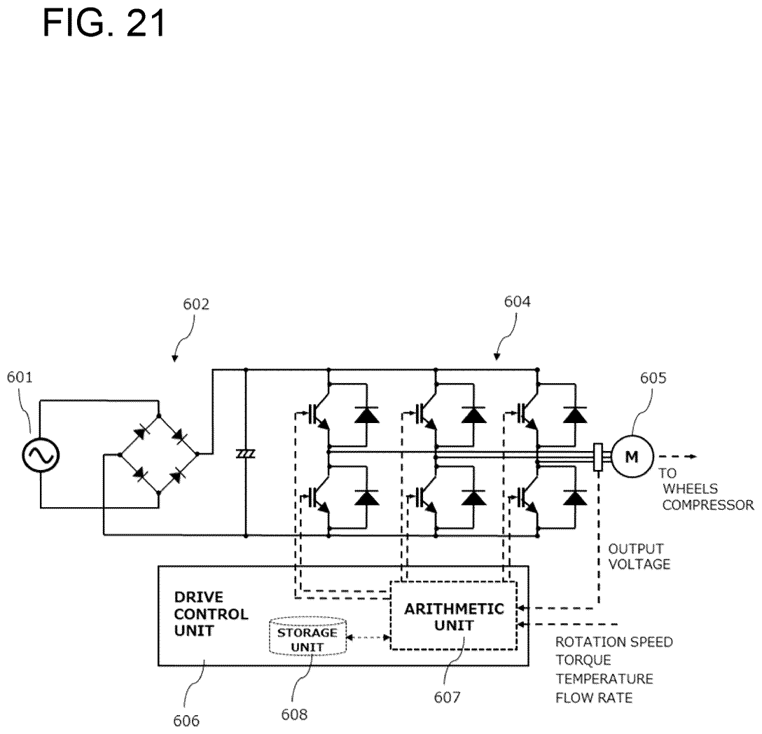

FIG. 21 shows the circuit configuration of FIG. 20. As shown in FIG. 21, the module unit of the disclosure is provided for switching control by, for example, being applied to the AC/DC converter 602 and the inverter 604 as a Schottky barrier diode. The AC/DC converter 602 has, for example, a circuit configuration in which Schottky barrier diodes are arranged in a bridge-shaped, to perform a direct-current conversion by converting and rectifying the negative component of the input voltage to a positive voltage. Schottky barrier diodes may also be applied to a switching circuit in IGBT of the inverter 604 to perform switching control. The voltage may be stabilized by interposing a capacitor (such as an electrolytic capacitor) between the AC/DC converter 602 and the inverter 604.

As indicated by a dotted line in FIG. 21, an arithmetic unit 607 including a CPU and a storage unit 608 including a nonvolatile memory are provided in the drive control unit 606. Signal input to the drive control unit 606 is given to the arithmetic unit 607, and a feedback signal for each semiconductor element is generated by performing the programmed operation as necessary. The storage unit 608 temporarily holds the calculation result by the arithmetic unit 607, stores physical constants and functions necessary for driving control in the form of a table, and outputs the physical constants, functions, and the like to the arithmetic unit 607 as appropriate. The arithmetic unit 607 and the storage unit 608 may be provided by a known configuration, and the processing capability and the like thereof may be arbitrarily selected.

In such a control system 600, similarly to the control system 500 shown in FIGS. 18 and 19, a diode or a switching element such as a thyristor, a power transistor, an IGBT, a MOSFET or the like is also applied for the purpose of the rectification operation and switching operation of the AC/DC converter 602 and the inverter 604. Switching performance may be improved by the use of gallium oxide (Ga2O3), particularly corundum-type gallium oxide (α-Ga2O3), as materials for these semiconductor elements. Further, extremely outstanding switching performance may be expected and miniaturization and cost reduction of the control system 600 may be realized by applying a module unit or an electronic device of the disclosure. That is, each of the AC/DC converter 602 and the inverter 604 may be expected to have the benefit of the disclosure, and the effects and the advantages of the disclosure may be expected in any one or combination of the AC/DC converter 602 and the inverter 604, or in any of the AC/DC converter 602 and the inverter 604 together with the drive control unit 606.

Although the motor 605 has been exemplified in FIGS. 20 and 21, the driving object is not necessarily limited to those that operate mechanically. Many devices that require an AC voltage may be a driving object. It is possible to apply the control system 600 as long as electric power is obtained from AC power source to drive the driving object. The control system 600 may be applied to the driving control of any electric equipment such as infrastructure equipment (electric power facilities such as buildings and factories, telecommunication facilities, traffic control facilities, water and sewage treatment facilities, system equipment, labor-saving equipment, trains and the like) and home appliances (refrigerators, washing machines, personal computers, LED lighting equipment, video equipment, audio equipment and the like).

### [Additional Note]

As described above, the present embodiments include the following disclosure.

### [Structure 1]

A module unit including: a wiring substrate; a power element-embedded substrate mounted on the wiring substrate; and a metal block disposed on a side of the wiring substrate on which the power element-embedded substrate is mounted, the metal block covering at least a portion of the power element-embedded substrate, the metal block having a recessed portion on a side thereof facing the power element-embedded substrate, at least a portion of the power element-embedded substrate is located in the recessed portion.

### [Structure 2]

The module unit according to [Structure 1], wherein a periphery of the power element-embedded substrate is covered with the recessed portion.

### [Structure 3]

The module unit according to [Structure 1] or [Structure 2], wherein a depth of the recessed portion is not more than 5 mm.

### [Structure 4]

The module unit according to any one of [Structure 1] to [Structure 3], wherein the power element-embedded substrate includes a wiring layer, a retention layer, an insulation layer located between the wiring layer and the retention layer, and a power element, wherein the power element is embedded in the insulation layer.

### [Structure 5]

The module unit according to any one of [Structure 1] to [Structure 4], wherein the power element constitutes a portion of a power conversion circuit.

### [Structure 6]

The module unit according to any one of [Structure 1] to [Structure 5], wherein a gate driver is further mounted on a same side of the wiring substrate as the power element-embedded substrate, and at least a portion of the gate driver is located inside the recessed portion.

### [Structure 7]

The module unit according to any one of [Structure 1] to [Structure 6], wherein a gate driver is further mounted on a surface side of the wiring substrate opposite to the power element-embedded substrate.

### [Structure 8]

The module unit according to any one of [Structure 1] to [Structure 7], further including an other power element-embedded substrate, wherein the other power element-embedded substrate is mounted on a same side of the wiring substrate as the power element-embedded substrate.

### [Structure 9]

The module unit according to any one of [Structure 1] to [Structure 8], wherein the metal block has an other recessed portion on the side thereof facing the power element-embedded substrate, and at least a portion of the other power element-embedded substrate is located inside the other recessed portion.

### [Structure 10]

The module unit according to any one of [Structure 1] to [Structure 9], wherein the metal block is at a same potential as a ground potential of the power conversion circuit.

### [Structure 11]

The module unit according to any one of [Structure 1] to [Structure 9], wherein the metal block is in direct contact with a ground electrode of the wiring substrate.

### [Structure 12]

The module unit according to any one of [Structure 1] to [Structure 11], wherein an insulating member is provided between the metal block and the power element-embedded substrate.

### [Structure 13]

The module unit according to any one of [Structure 1] to [Structure 12], wherein the outermost surface of the power element-embedded substrate on the metal block side is at ground potential, and the outermost surface is in direct contact with the metal block.

### [Structure 14]

The module unit according to any one of [Structure 1] to [Structure 13], wherein the metal block is connected to a cooler.

### [Structure 15]

The module unit according to any one of [Structure 1] to [Structure 14], wherein a heat dissipation member is disposed on a surface of the wiring substrate opposite to a surface on which the power element-embedded substrate is mounted.

### [Structure 16]

An electronic device including: a module unit and a mounting substrate, the module unit being longitudinally provided on the mounting substrate, the module unit being the module unit according to any one of [Structure 1] to [Structure 15].

It should be noted that it is naturally possible to combine some or all of the above-described embodiments of the present disclosure, or to apply some of the components to other embodiments, and such combinations and applications also belong to the embodiments of the present disclosure.

### REFERENCE SIGNS LIST

1a, 1b Wiring substrate
2a, 2b Power element-embedded substrate
3a, 3b Metal block (heat dissipation member)
3c Cooler (heat radiation fin)
4a, 4b Insulating member
5a, 5b Recessed portion
6 Ground electrode
7a, 7b Gate driver
8a Electrode pin
8b Hole
10a, 10b, 10c Module unit
10d, 10e, 10f Module unit
10g, 10h, 10i Module unit
10j Module unit
11 Mounting substrate
12 Passive component
14a Resin portion
14b Pin portion
14c Pin portion
31a Power supply pin
31b Signal pin
32a Input pin
32b Output pin
32c GND pin
101a, 101b Transistor
102a, 102b Diode
111 First wiring layer (upper wiring layer)
112 Retention layer (second wiring layer/lower wiring layer)
115 Insulator
117 Electrical conduction via
118 Base material
119a Insulating protective layer
119b Insulating protective layer
120 Through hole
111a Adhesion layer (conductive adhesion layer)
111b Adhesion layer (conductive adhesion layer)
500 Control system
501 Battery (power source)
502 Boost converter
503 Buck converter
504 Inverter
505 Motor (to be driven)
506 Drive control unit
507 Calculation unit
508 Storage unit
600 Control system
601 Three-phase alternating current power source (power source)
602 AC/DC converter
604 Inverter
605 Motor (to be driven)
606 Drive control unit
607 Calculation unit
608 Storage unit

What is claimed is:

1. A module unit comprising: a wiring substrate; a power element-embedded substrate mounted on the wiring substrate; and a metal block disposed on a side of the wiring substrate on which the power element-embedded substrate is mounted, the metal block covering at least a portion of the power element-embedded substrate, the metal block having a recessed portion on a side thereof facing the power element-embedded substrate, at least a portion of the power element-embedded substrate is located in the recessed portion.

2. The module unit according to claim 1, wherein a periphery of the power element-embedded substrate is covered with the recessed portion.

3. The module unit according to claim 1, wherein a depth of the recessed portion is not more than 5 mm.

4. The module unit according to claim 1, wherein the power element-embedded substrate comprises a wiring layer, a retention layer, an insulation layer located between the wiring layer and the retention layer, and a power element, wherein the power element is embedded in the insulation layer.

5. The module unit according to claim 4, wherein the power element constitutes a portion of a power conversion circuit.

6. The module unit according to claim 1, wherein a gate driver is further mounted on a same side of the wiring substrate as the power element-embedded substrate, and at least a portion of the gate driver is located inside the recessed portion.

7. The module unit according to claim 1, wherein a gate driver is further mounted on a surface side of the wiring substrate opposite to the power element-embedded substrate.

8. The module unit according to claim 1, further comprising an other power element-embedded substrate, wherein the other power element-embedded substrate is mounted on a same side of the wiring substrate as the power element-embedded substrate.

9. The module unit according to claim 8, wherein the metal block has an other recessed portion on the side thereof facing the power element-embedded substrate, and at least a portion of the other power element-embedded substrate is located inside the other recessed portion.

10. The module unit according to claim 5, wherein the metal block is at a same potential as a ground potential of the power conversion circuit.

11. The module unit according to claim 1, wherein the metal block is in direct contact with a ground electrode of the wiring substrate.

12. The module unit according to claim 1, wherein an insulating member is provided between the metal block and the power element-embedded substrate.

13. The module unit according to claim 1, wherein the outermost surface of the power element-embedded substrate on the metal block side is at ground potential, and the outermost surface is in direct contact with the metal block.

14. The module unit according to claim 1, wherein the metal block is connected to a cooler.

15. The module unit according to claim 1, wherein a heat dissipation member is disposed on a surface of the wiring substrate opposite to a surface on which the power element-embedded substrate is mounted.

16. An electronic device comprising: a module unit and a mounting substrate, the module unit being longitudinally provided on the mounting substrate, the module unit being the module unit according to claim 1.
